(19) United States
(12) Patent Application Publication
(10) Pub. No.: US 2021/0389362 A1
(43) Pub. Date: Dec. 16, 2021

(54) SEMICONDUCTOR DEVICE, DETECTION METHOD, ELECTRONIC APPARATUS, AND ELECTRONIC APPARATUS CONTROL METHOD

(71) Applicant: SONY SEMICONDUCTOR SOLUTIONS CORPORATION, Kanagawa (JP)

(72) Inventors: Shigetaka MORI, Kanagawa (JP); Manabu TOMITA, Kanagawa (JP)

(73) Assignee: SONY SEMICONDUCTOR SOLUTIONS CORPORATION, Kanagawa (JP)

(21) Appl. No.: 17/283,153

(22) PCT Filed: Oct. 16, 2019
(86) PCT No.: PCT/JP2019/040741

§ 371 Date: Apr. 6, 2021

(30) Foreign Application Priority Data
Oct. 17, 2018 (JP) 2018-195635

(51) Int. Cl. G01R 31/26; G01R 29/10; H01L 21/66; H01L 27/088

(52) U.S. Cl. CPC G01R 31/2621; H01L 27/088; H01L 22/34; G01R 29/10

(57) ABSTRACT

An effect of PID is measured with higher accuracy by using an oscillation circuit. There is provided a semiconductor device including at least one measurement transistor a gate of which is electrically connected to an antenna unit that functions as an antenna in a plasma process, a selection transistor a source of which is electrically connected to the gate of the measurement transistor in parallel to the antenna unit; and an oscillation circuit electrically connected to a source of the measurement transistor and having an oscillation frequency that changes according to a threshold voltage of the measurement transistor.

### TECHNICAL FIELD

The present disclosure relates to a semiconductor device, a detection method, an electronic apparatus, and an electronic apparatus control method.

### BACKGROUND ART

It is known that damage called PID (Plasma (Process) Induced Damage) is caused in a field-effect transistor (FET) during a plasma process adopted in a manufacturing step of a semiconductor device.

PID is caused in a case where a wire or a via connected to a gate of an FET functions as an antenna during a plasma process and where charges contained in plasma are attracted to the antenna and then flow into a gate insulation film of the FET as a current. PID causes a defect or a carrier trap level in an interface between the gate insulation film and a semiconductor substrate or in the gate insulation film, and therefore affects a threshold voltage and a gate leakage of the FET.

In a case of deviation from a range of variations considered at the time of designing as a result of a change of the threshold voltage of the FET produced by PID, an operation of a semiconductor device including the FET may be affected. Accordingly, it is important to accurately measure an effect of PID on a threshold voltage and a gate leakage of the semiconductor device and reflect the effect to process conditions, a device structure, a circuit design, and the like on the basis of a measured result.

For accurately measuring the effect of PID, a measurement circuit (also referred to a Test Element Group: TEG) is thus disposed within the semiconductor device to measure the effect of PID.

For example, this measurement circuit has such a structure that includes multiple FETs and a pad, the multiple FETs each having a different area ratio of a gate to an antenna unit (i.e., a wire or a via functioning as an antenna during a plasma process) connected to the gate, the pad being connected to each gate, source, and drain of the multiple FETs and to each terminal of a semiconductor substrate through wires. The measurement circuit is capable of evaluating an effect of PID produced by the antenna unit for each area ratio of the antenna unit to the gate, by measuring characteristics of a gate voltage and a drain current in each of the FETs and deriving a threshold voltage for each of the FETs.

Meanwhile, as described in NPL 1 below, a technology for monitoring characteristics of an FET by using a ring oscillator has been devised. Specifically, according to the technology described in NPL 1, an FET is provided between a ring oscillator and a VDD wire or a VSS wire to monitor characteristics of the FET on the basis of an oscillation frequency of the ring oscillator.

### CITATION LIST

### Non Patent Literature

### [NPL 1]

Kelin J. Kuhn etc., “Process Technology Variation” IEEE TRANSACTIONS ON ELECTRON DEVICES VOL. 58 NO. 8, AUGUST 2011

### SUMMARY

### Technical Problem

However, sufficient studies have not been made for application of the structure described in NPL 1 to a measurement circuit which evaluates an effect of PID. It has therefore been demanded to study a specific structure of a measurement circuit which evaluates an effect of PID by using an oscillation circuit.

Accordingly, the present disclosure proposes a novel and improved semiconductor device capable of measuring an effect of PID with higher accuracy by using an oscillation circuit.

### Solution to Problem

According to the present invention, there is provided a semiconductor device including at least one measurement transistor a gate of which is electrically connected to an antenna unit that functions as an antenna in a plasma process; a selection transistor a source of which is electrically connected to the gate of the measurement transistor in parallel to the antenna unit; and an oscillation circuit electrically connected to a source of the measurement transistor and having an oscillation frequency that changes according to a threshold voltage of the measurement transistor.

Further, according to the present disclosure, there is provided a detection method including controlling a measurement transistor of a semiconductor device to be brought into an on-state by controlling a selection transistor of the semiconductor device to be brought into an on-state, the semiconductor device including at least the one measurement transistor a gate of which is electrically connected to an antenna unit that functions as an antenna in a plasma process, the selection transistor a source of which is electrically connected to the gate of the measurement transistor in parallel to the antenna unit, and an oscillation circuit electrically connected to a source of the measurement transistor and having an oscillation frequency that changes according to a threshold voltage of the measurement transistor; and measuring an oscillation frequency of the oscillation circuit when the measurement transistor is in the on-state, and detecting presence or absence of a difference between the threshold voltage of the measurement transistor and an ideal value of the threshold voltage on the basis of the measured oscillation frequency.

Further, according to the present disclosure, there is provided an electronic apparatus including a semiconductor device that includes at least one measurement transistor a gate of which is electrically connected to an antenna unit that functions as an antenna in a plasma process, a selection transistor a source of which is electrically connected to the gate of the measurement transistor in parallel to the antenna unit, and an oscillation circuit electrically connected to a source of the measurement transistor and having an oscillation frequency that changes according to a threshold voltage of the measurement transistor; a control unit that controls an on-state or an off-state of the measurement transistor by controlling an on-state or an off-state of the selection transistor; a measurement unit that measures an oscillation frequency of the oscillation circuit when the measurement transistor is in the on-state; a detection unit that detects presence or absence of a difference between the threshold voltage of the measurement transistor and an ideal value of the threshold voltage on the basis of each of the measured oscillation frequencies; and a processing unit that performs processing of correcting an effect produced by the plasma process in a case where the difference is detected by the detection unit.

In addition, according to the present disclosure, there is provided an electronic apparatus control method including controlling a measurement transistor of an electronic apparatus to be brought into an on-state by controlling a selection transistor of the electronic apparatus to be brought into an on-state, the electronic apparatus including a semiconductor device that includes at least the one measurement transistor a gate of which is electrically connected to an antenna unit that functions as an antenna in a plasma process, the selection transistor a source of which is electrically connected to the gate of the measurement transistor in parallel to the antenna unit, and an oscillation circuit electrically connected to a source of the measurement transistor and having an oscillation frequency that changes according to a threshold voltage of the measurement transistor; measuring an oscillation frequency of the oscillation circuit when the measurement transistor is in the on-state, and detecting presence or absence of a difference between the threshold voltage of the measurement transistor and an ideal value of the threshold voltage on the basis of the measured oscillation frequency; and performing control to correct an effect produced by the plasma process in a case where the difference is detected.

### BRIEF DESCRIPTION OF DRAWINGS

FIG. 1A is an explanatory diagram explaining occurrence of PID in a plasma process.

FIG. 1B is an explanatory diagram explaining occurrence of PID in a plasma process.

FIG. 2A is an explanatory diagram depicting an example of a method for evaluating an effect of PID on an FET.

FIG. 2B is an explanatory diagram depicting an example of a method for evaluating an effect of PID on an FET.

FIG. 2C is an explanatory diagram depicting an example of a method for evaluating an effect of PID on an FET.

FIG. 3 is a circuit diagram explaining a structure example of a semiconductor device according to a first embodiment of the present disclosure.

FIG. 4 is a circuit diagram depicting an extracted configuration between a VDD wire and a VSS wire of the semiconductor device according to the same embodiment.

FIG. 5A is a graph representing a detection result obtained in a case of reduction of PID achieved by a protection element provided at a gate of a measurement transistor.

FIG. 5B is a graph representing a detection result obtained in a case of intentionally causing PID in a plasma process.

FIG. 6 is a circuit diagram explaining s structure example of a semiconductor device according to a comparative example.

FIG. 7 is a circuit diagram depicting an extracted configuration between a VDD wire and a VSS wire of the semiconductor device according to the comparative example.

FIG. 8A is a circuit diagram depicting a structure example of a semiconductor device according to a first modification.

FIG. 8B is a circuit diagram depicting a structure example of a semiconductor device according to a second modification.

FIG. 8C is a circuit diagram depicting a structure example of a semiconductor device according to a third modification.

FIG. 8D is a circuit diagram depicting a structure example of a semiconductor device according to a fourth modification.

FIG. 9 is a flowchart presenting an example of an operation of the semiconductor device according to the same embodiment.

FIG. 10 is a block diagram depicting a configuration of an electronic apparatus according to a first application example.

FIG. 11 is a block diagram depicting a configuration of an electronic apparatus according to a second application example.

FIG. 12 is a block diagram depicting a configuration of an electronic apparatus according to a third application example.

FIG. 13 is a circuit diagram explaining a structure example of a semiconductor device according to a second embodiment of the present disclosure.

FIG. 14 is a circuit diagram depicting a more specific circuit structure of the semiconductor device according to the same embodiment.

FIG. 15 is a circuit diagram depicting a more specific circuit structure of an oscillation circuit.

FIG. 16 is a graph representing frequency characteristics of the oscillation circuit.

FIG. 17 is a graph representing a relation between an input voltage and an output voltage in a source follower circuit.

FIG. 18 is a diagram for explaining a shift of a used voltage range performed by an adjustment circuit according to a third embodiment.

FIG. 19 is a graph representing a relation between a change range and frequency characteristics before and after a shift performed by the adjustment circuit according to the third embodiment.

FIG. 20 is a diagram for explaining an output voltage from a source follower circuit according to the third embodiment.

FIG. 21 is a circuit diagram depicting a general configuration example of an adjustment circuit according to a first specific example of the third embodiment.

FIG. 22 is a circuit diagram depicting a general configuration example of an adjustment circuit according to a second specific example of the third embodiment.

FIG. 23 is a diagram for explaining a shift of an output voltage in a case of control of a ratio of an on-resistance of a P-type transistor to an on-resistance of an N-type transistor in a shift circuit according to the third embodiment.

FIG. 24 is a diagram for explaining a shift of an output voltage in a case of control of a ratio of an on-resistance of a P-type transistor to an on-resistance of an N-type transistor in the shift circuit according to the third embodiment.

FIG. 25 is a diagram for explaining a configuration of the shift circuit in a case where an oscillation frequency of an oscillation circuit is desired to be increased and in a case where the oscillation frequency of the oscillation circuit is desired to be decreased in the third embodiment.

FIG. 26 is a circuit diagram depicting a general configuration example of the shift circuit according to the third embodiment.

FIG. 27 is a graph representing an example of an output voltage output from the shift circuit in a case where the number of Fingers of each of transistors included in the shift circuit depicted in FIG. 26 is switched.

FIG. 28 is a circuit diagram depicting a general configuration example of an adjustment circuit according to a third specific example of the third embodiment.

FIG. 29 is a circuit diagram depicting a general configuration example of an adjustment circuit according to a fourth specific example of the third embodiment.

FIG. 30 is a circuit diagram explaining a structure example of a semiconductor device according to a first example of the third embodiment.

FIG. 31 is a circuit diagram explaining a structure example of a semiconductor device according to a second example of the third embodiment.

FIG. 32 is a circuit diagram explaining a structure example of a semiconductor device according to a third example of the third embodiment.

FIG. 33 is a circuit diagram explaining a structure example of a semiconductor device according to a fourth example of the third embodiment.

FIG. 34 is a circuit diagram explaining a structure example of a semiconductor device according to a fifth example of the third embodiment.

FIG. 35 is a circuit diagram explaining a structure example of a semiconductor device according to a sixth example of the third embodiment.

FIG. 36 is a diagram depicting a circuit configuration of a semiconductor device used to execute a demonstration experiment in the third embodiment.

FIG. 37 is a graph presenting a result obtained by the present demonstration experiment in the third embodiment.

FIG. 38 is a graph representing an example of voltage values of mismatch components in a case of presence of damage from an antenna and in a case of absence of damage from the antenna in the third embodiment.

### DESCRIPTION OF EMBODIMENTS

Preferred embodiments of the present disclosure will hereinafter be described in detail with reference to the accompanying drawings. Note that constituent elements having substantially identical functional configurations are given identical reference signs in the present description and the drawings to omit repetitive description.

Note that the description will be presented in a following order.

0. Background of technology according to present disclosure

### 1. First Embodiment

1.1. Structure example
1.2. PID evaluation
1.3. Superiority of semiconductor device
1.4. Modifications
1.5. Operation example
1.6. Application examples

### 2. Second Embodiment

2.1. Structure example
2.2. Specific example

### 3. Third Embodiment

3.1. Frequency characteristics of oscillation circuit and used voltage range
3.2. Role of adjustment circuit
   3.2.1. Limit of voltage change range
   3.2.2. Shift of used voltage range
   3.3. Adjustment circuit
      3.3.1. Output voltage Vout from source follower circuit
      3.3.2. Specific examples of adjustment circuit
         3.3.2.1. First specific example
         3.3.2.2. Second specific example
         3.3.2.3. Third specific example
         3.3.2.4. Fourth specific example
         3.3.2.5. Other examples
   3.4. Structure example
      3.4.1. First example
      3.4.2. Second example
      3.4.3. Third example
      3.4.4. Fourth example
      3.4.5. Fifth example
      3.4.6. Sixth example
      3.4.7. Other examples
   3.5. Demonstration experiment result
      3.5.1. Effect of threshold voltage of load transistor included in limit circuit
   3.6. Summary

### 0. Background of Technology According to Present Disclosure

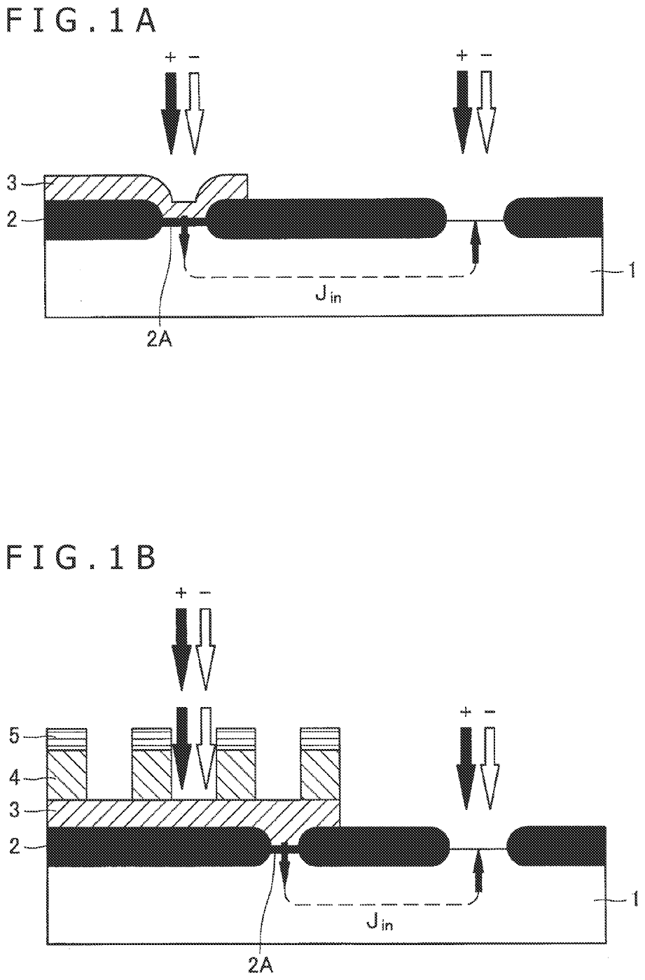

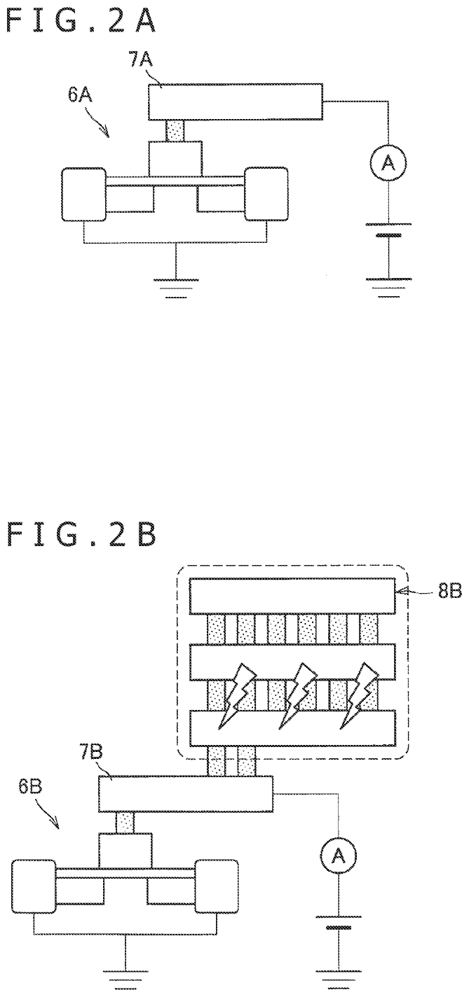

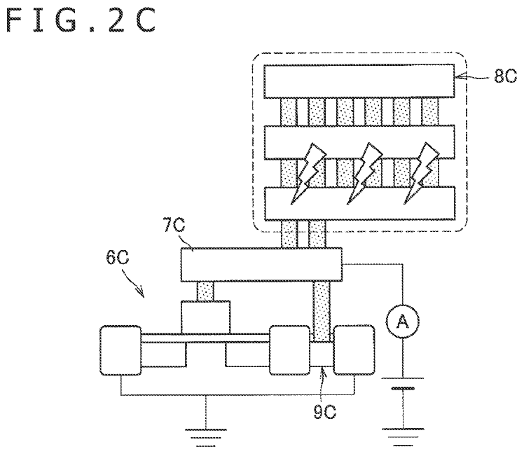

First, the background of the technology according to the present disclosure will be described with reference to FIGS. 1A to 2C. FIGS. 1A and 1B are explanatory diagrams each explaining occurrence of PID in a plasma process.

As depicted in FIG. 1A, in a case where a lamination stack produced by stacking an insulation layer 2, a conductive layer 3, and the like on a semiconductor substrate 1 is loaded to perform a process using plasma (e.g., etching, CVD (Chemical Vapor Deposition), PVD (Physical Vapor Deposition), or sputtering), positive ions and electrons electrically separated by plasma are applied to the lamination stack.

The conductive layer 3 has been brought into a floating state by the insulation layer 2 and an insulation thin film 2A. Accordingly, charges of the positive ions and the electrons thus applied are accumulated in the conductive layer 3. In a case where an electric field between the conductive layer 3 containing the accumulated charges and the semiconductor substrate 1 exceeds a threshold, a current Jin flows from the conductive layer 3 toward the semiconductor substrate 1. At this time, a large current flows in the insulation thin film 2A (corresponding to a gate insulation film, for example) between the conductive layer 3 and the semiconductor substrate 1. Accordingly, the insulation thin film 2A is damaged.

Such a phenomenon is also referred to PID (Plasma (Process) Induced Damage). PID causes a defect or a carrier trap level within the insulation thin film 2A or in an interface between the insulation thin film 2A and the semiconductor substrate 1, and therefore, a threshold voltage Vth of an FET in which the insulation thin film 2A is used as a gate insulation film is changed, and a gate leakage is increased.

Particularly, in a case where a wiring layer 4 formed on the conductive layer 3 is etched by using a mask 5 as depicted in FIG. 1B, more charges are accumulated in the wiring layer 4 and the conductive layer 3 when the wiring layer 4 functions as an antenna. In such a case, a larger current flows in the insulation thin film 2A. Accordingly, an effect of PID increases in a plasma process performed during formation of a wire or a via.

As described above, in a case where the gate insulation film is damaged by PID, the threshold voltage Vth is changed and a gate leakage is increased in the FET. As a result, it may be difficult to achieve the designed performance with the FET affected by PID. Accordingly, it is essential to evaluate an effect of PID on the FET in the semiconductor device.

FIGS. 2A to 2C each depict an example of a method for evaluating an effect of PID on an FET. Note that FIG. 2A depicts a structure of an FET as a reference, that FIG. 2B depicts a structure of an FET as a measurement target, and that FIG. 2C depicts a structure of an FET for evaluation of an effect of a protection element.

For example, an effect on an FET by PID can be evaluated by measuring the threshold voltage Vth and gate leakage of each FET differently affected by PID, and then comparing the measured threshold voltages Vth and gate leakages. The threshold voltage Vth can be derived from characteristics of a voltage applied to a gate and of a drain current in the FET. The gate leakage can be evaluated by measuring, at a gate or a body, a leakage current which flows when a voltage is applied between the gate and the body, a source, and a drain.

For example, it is considered that PID has substantially no effect on an FET 6A depicted in FIG. 2A because a wire and a via functioning as an antenna are not connected to a gate through a gate wire 7A. Further, it is considered that a change or the like of the threshold voltage Vth has been produced by PID in an FET 6B depicted in FIG. 2B because a wire and via 8B functioning as an antenna are connected to a gate through a gate wire 7B. Accordingly, a change of the threshold voltage Vth produced by PID can be evaluated by comparing the respective threshold voltages Vth of the FET 6A and the FET 6B.

On the other hand, as for an FET 6C depicted in FIG. 2C, the wire and via 8B functioning as an antenna are connected to a gate through the gate wire 7B, and a protection element 9C (e.g., diode or the like) for releasing charges generated in a plasma process is provided. The FET 6C can thus prevent a large current from flowing into a gate insulation film by using the protection element 9C, and therefore, it is considered that damage to a gate insulation film of the FET 6C caused by PID is avoided. Accordingly, a reduction level achieved by the protection element 9C for the damage given to the gate insulation film by PID can be evaluated by comparison between the respective threshold voltages Vth of the FET 6B and the FET 6C.

However, according to the method described above, a pad (PAD) for extracting a current or a voltage is provided for each of the gate, the body, the source, and the drain in each of the FETs 6A, 6B, and 6C. In such a case, an area of a measurement circuit for evaluating PID increases. Accordingly, a semiconductor device which executes predetermined functions increases in size when the method described above is applied to a measurement circuit incorporated in the semiconductor device. Therefore, it is not practical to execute the above method.

The technology according to the present disclosure has been developed in consideration of the abovementioned circumstances. The technology according to the present disclosure is capable of evaluating an effect of PID with higher accuracy by using a small-scale measurement circuit provided within a semiconductor device which executes predetermined functions.

Specifically, the technology according to the present disclosure evaluates an effect of PID with a small-scale circuit by electrically connecting an oscillation circuit to a measurement transistor a gate of which is electrically connected to an antenna unit that functions as an antenna in a plasma process. The oscillation circuit has an oscillation frequency that changes according to a threshold voltage of the measurement transistor.

Further, the technology according to the present disclosure selects the measurement transistor which measures a threshold voltage by using a selection transistor electrically connected to the gate of the measurement transistor. In such a manner, an effect of the threshold voltage of the measurement transistor on the oscillation frequency of the oscillation circuit is allowed to increase. Accordingly, the threshold voltage of the measurement transistor can be evaluated with higher accuracy.

The technology according to the present disclosure will hereinafter be described more specifically while the description thereof is separated into a first embodiment and a second embodiment.

### 1. First Embodiment

### (1.1. Structure Example)

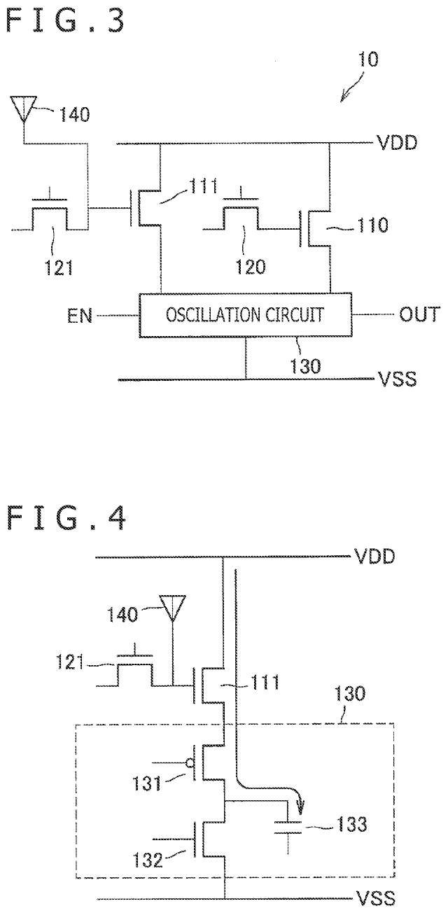

First, a structure example of a semiconductor device according to the first embodiment of the present disclosure will be described with reference to FIG. 3. FIG. 3 is a circuit diagram explaining the structure example of the semiconductor device according to the present embodiment.

As depicted in FIG. 3, a semiconductor device 10 according to the present embodiment includes an antenna unit 140, a selection transistor 121, a measurement transistor 111, a reference selection transistor 120, a reference transistor 110, and an oscillation circuit 130.

A VDD wire and a VSS wire each supply a reference potential to the semiconductor device 10. The VDD wire is a wire having a higher potential than that of the VSS wire. The VDD wire is, for example, a power source wire while the VSS wire is, for example, a ground wire.

The antenna unit 140 is a structure body which functions as an antenna in a plasma process during a manufacturing step of the semiconductor device 10. Specifically, the antenna unit 140 functions as an antenna which attracts positive ions and electrons electrically separated by plasma during etching, CVD, PVD, sputtering, or the like for processing the semiconductor device 10 by using plasma. For example, the antenna unit 140 may be a wire, an interlayer electrode, a substrate through electrode (what is called a Through-Silicon Via: TSV), an electrode between chips (Through-Chip Via: TCV), or an electrode junction structure between chips (what is called Cu—Cu junction) each included in a circuit of the semiconductor device 10, or may be a combination of these.

As described above, the antenna unit 140 electrically connected to a gate of the measurement transistor 111 causes PID in the measurement transistor 111 by using charges accumulated in the antenna unit 140 during the plasma process. Note that an effect by PID is determined by a plane area ratio of the gate of the measurement transistor 111 to the antenna unit 140 (also called antenna ratio). Therefore, according to the semiconductor device 10, the multiple measurement transistors 111 each gate of which is electrically connected to the antenna unit 140 may be provided for each area ratio of the gate of the measurement transistor 111 to the antenna unit 140.

The measurement transistor 111 is an FET provided such that the antenna unit 140 is electrically connected to a gate of the FET and that the oscillation circuit 130 is electrically connected to a source of the FET. Specifically, the measurement transistor 111 is provided between the oscillation circuit 130 and the VDD wire or the VSS wire. For example, as depicted in FIG. 3, the measurement transistor 111 may be provided between the VDD wire and the oscillation circuit 130. Alternatively, as described below, the measurement transistor 111 may be provided between the VSS wire and the oscillation circuit 130.

The antenna unit 140 is electrically connected to the gate of the measurement transistor 111. Accordingly, PID during the plasma process changes the threshold voltage Vth of the measurement transistor 111. In such a case, a channel resistance of the measurement transistor 111 changes according to the change of the threshold voltage Vth. Accordingly, the measurement transistor 111 is allowed to change a voltage applied to the oscillation circuit 130 to change an oscillation frequency of the oscillation circuit 130. In such a manner, the measurement transistor 111 is enabled to control the oscillation frequency of the oscillation circuit 130 according to the threshold voltage Vth of the measurement transistor 111.

In a case where the measurement transistor 111 is provided on the VDD wire side with respect to the oscillation circuit 130, the measurement transistor 111 may be configured as an N-type transistor. On the other hand, in a case where the measurement transistor 111 is provided on the VSS wire side with respect to the oscillation circuit 130, the measurement transistor 111 may be configured as a P-type transistor. In such a manner, the measurement transistor 111 is enabled to increase a change of the oscillation frequency of the oscillation circuit 130 produced according to a change of the threshold voltage Vth of the measurement transistor 111.

The selection transistor 121 is an FET provided such that a source of the selection transistor 121 is electrically connected to the gate of the measurement transistor 111 in parallel to the antenna unit 140. The selection transistor 121 controls an on-state or an off-state of the measurement transistor 111 to switch to the measurement transistor 111, so that the measurement transistor 111 functions as a transistor electrically connected to the oscillation circuit 130. Specifically, the selection transistor 121 brings the measurement transistor 111 into the on-state to adjust a voltage applied to the oscillation circuit 130, to a value calculated by subtracting a voltage corresponding to the channel resistance of the measurement transistor 111 from a potential difference between the VDD wire and the VSS wire. At this time, the reference selection transistor 120 is brought into an off-state.

The selection transistor 121 may be provided as an FET of the same conductivity type as that of the measurement transistor 111. Specifically, in a case where the selection transistor 121 and the measurement transistor 111 are provided on the VDD wire side with respect to the oscillation circuit 130, the selection transistor 121 may be configured as an N-type transistor which is of the same type as that of the measurement transistor 111. On the other hand, in a case where the selection transistor 121 and the measurement transistor 111 are provided on the VSS wire side with respect to the oscillation circuit 130, the selection transistor 121 may be configured as a P-type transistor which is of the same type as that of the measurement transistor 111.

For example, in a case of use of a CMOS (complementary MOS) transfer gate including a P-type transistor and an N-type transistor as a switching element in place of the selection transistor 121, there is a possibility that an effect of PID on the measurement transistor 111 is reduced. Such reduction of the effect of PID is achievable because the CMOS transfer gate also has a function of a protection element providing protection from PID caused in the measurement transistor 111 by the antenna unit 140. Accordingly, by using the selection transistor 121 not having the function of the protection element, the measurement transistor 111 is allowed to reflect the effect of PID more accurately. As a result, PID measurement accuracy of the semiconductor device 10 can be improved.

The reference transistor 110 is an FET provided such that the oscillation circuit 130 is electrically connected to a source of the reference transistor 110. However, that the reference transistor 110 is provided such that the antenna unit 140 is not connected to a gate of the reference transistor 110. Specifically, the reference transistor 110 is provided between the oscillation circuit 130 and the VDD wire or the VSS wire, similarly to the measurement transistor 111. For example, as depicted in FIG. 3, the reference transistor 110 may be provided between the VDD wire and the oscillation circuit 130. Alternatively, as described below, the reference transistor 110 may be provided between the VSS wire and the oscillation circuit 130.

The reference transistor 110 is different from the measurement transistor 111 in that the wire or the via functioning as an antenna in the plasma process is not electrically connected to the gate of the reference transistor 110. Specifically, the reference transistor 110 is provided to measure the threshold voltage Vth in a case of the absence of the effect of PID.

Accordingly, the reference transistor 110 is provided as an FET similar to the measurement transistor 111 except that the antenna unit 140 is not connected to the gate of the reference transistor 110. Specifically, in a case where the reference transistor 110 is provided on the VDD wire side with respect to the oscillation circuit 130, the reference transistor 110 may be configured as an N-type transistor. On the other hand, in a case where the reference transistor 110 is provided on the VSS wire side with respect to the oscillation circuit 130, the reference transistor 110 may be configured as a P-type transistor.

The reference selection transistor 120 is an FET provided such that a source of the reference selection transistor 120 is electrically connected to the gate of the reference transistor 110. The reference selection transistor 120 controls an on-state or an off-state of the reference transistor 110 to switch to the reference transistor 110, so that the reference transistor 110 functions as a transistor electrically connected to the oscillation circuit 130. Specifically, the reference selection transistor 120 adjusts the voltage applied to the oscillation circuit 130, to a value calculated by subtracting a voltage corresponding to the channel resistance of the reference transistor 110 from the potential difference between the VDD wire and the VSS wire. At this time, the selection transistor 121 is brought into an off-state.

The reference selection transistor 120 is provided as an FET of the same conductivity type as that of the reference transistor 110, similarly to the selection transistor 121 and the measurement transistor 111. Specifically, in a case where the reference selection transistor 120 and the reference transistor 110 are provided on the VDD wire side with respect to the oscillation circuit 130, the reference selection transistor 120 may be configured as an N-type transistor which is of the same type as that of the reference transistor 110. On the other hand, in a case where the reference selection transistor 120 and the reference transistor 110 are provided on the VSS wire side with respect to the oscillation circuit 130, the reference selection transistor 120 may be configured as a P-type transistor which is of the same type as that of the reference transistor 110.

The oscillation circuit 130 is electrically connected to the source of the measurement transistor 111 or the reference transistor 110 and provided between the VDD wire and the VSS wire. The oscillation circuit 130 is an electric circuit which outputs an alternating current output at an oscillation frequency to an OUT terminal according to an input from an EN terminal. Specifically, the oscillation circuit 130 is a feedback type oscillation circuit which feeds back a part of an output to an input to produce a cyclic change of voltage. For example, the oscillation circuit 130 may be a ring oscillator that feeds back an output to which an odd number of inverting logics such as NOT or NOR are connected, to an input in a ring shape to generate a cyclic square wave. Either NOT or NOR included in the oscillation circuit 130 is replaced with NAND. The oscillation circuit 130 starts oscillation when one end of an input of the NAND receives, from the EN terminal, an input of a signal that gives an instruction on a start of an oscillation. According to such a configuration, the oscillation circuit 130 is simultaneously manufacturable by the same step as that of other transistors. Accordingly, a rise of manufacturing cost of the semiconductor device 10 can be reduced.

As will be described below, in the oscillation circuit 130, an oscillation frequency changes according to the threshold voltages Vth of the measurement transistor 111 and the reference transistor 110 electrically connected to the oscillation circuit 130. Accordingly, the semiconductor device 10 is capable of evaluating an effect of PID on the measurement transistor 111 by a comparison between an oscillation frequency in a case of electric connection of the reference transistor 110 to the oscillation circuit 130 and an oscillation frequency in a case of electric connection of the measurement transistor 111 to the oscillation circuit 130.

### (1.2. PID Evaluation)

A PID evaluation obtained by the semiconductor device 10 according to the present embodiment will subsequently be described with reference to FIGS. 4 to 7.

First, a PID evaluation example obtained by the semiconductor device 10 according to the present embodiment will be described with reference to FIG. 4. FIG. 4 is a circuit diagram depicting an extracted configuration between the VDD wire and the VSS wire of the semiconductor device 10.

As depicted in FIG. 4, the measurement transistor 111 the gate of which is connected to the antenna unit 140 and the selection transistor 121 in parallel, and a P-type transistor 131 and an N-type transistor 132 included in one inverter in the oscillation circuit 130 are provided in series between the VDD wire and the VSS wire in the semiconductor device 10. Further, a load capacitance 133 is electrically connected to the output side of the inverter.

Assuming herein that a capacitance of the load capacitance 133 is C, that a channel resistance of the measurement transistor 111 is R1, and that a channel resistance of the P-type transistor 131 is R2, a charging time t of the load capacitance 133 can be expressed by the following Equation (1).

t=(R1+R2)×C (1)

Accordingly, assuming that the oscillation circuit 130 is a ring oscillator to which N (N represent an odd number) inverters are connected, an oscillation frequency f of the oscillation circuit 130 can be expressed by the following Equation (2).

$$\begin{matrix}f = 1 / ( 2 \times N \times t ) \\ = 1 / \{ 2 \times N \times ( R 1 + R 2 ) \times C \}\end{matrix} \qquad ( 2 )$$

In a case where the threshold voltage Vth of the measurement transistor 111 increases as a result of PID caused in the measurement transistor 111, the channel resistance R1 increases according to the increase in the threshold voltage Vth. Accordingly, as can be seen from the Equation (2), the oscillation frequency f of the oscillation circuit 130 decreases. The semiconductor device 10 is therefore capable of detecting whether or not PID has been caused in the measurement transistor 111, by detecting a change of the oscillation frequency f. Further, the oscillation frequency f is in inverse proportion to the sum of the channel resistance R1 and the channel resistance R2. Accordingly, the semiconductor device 10 is capable of evaluating a change amount of the channel resistance R1 or the threshold voltage Vth produced by PID, on the basis of a change amount of the oscillation frequency f.

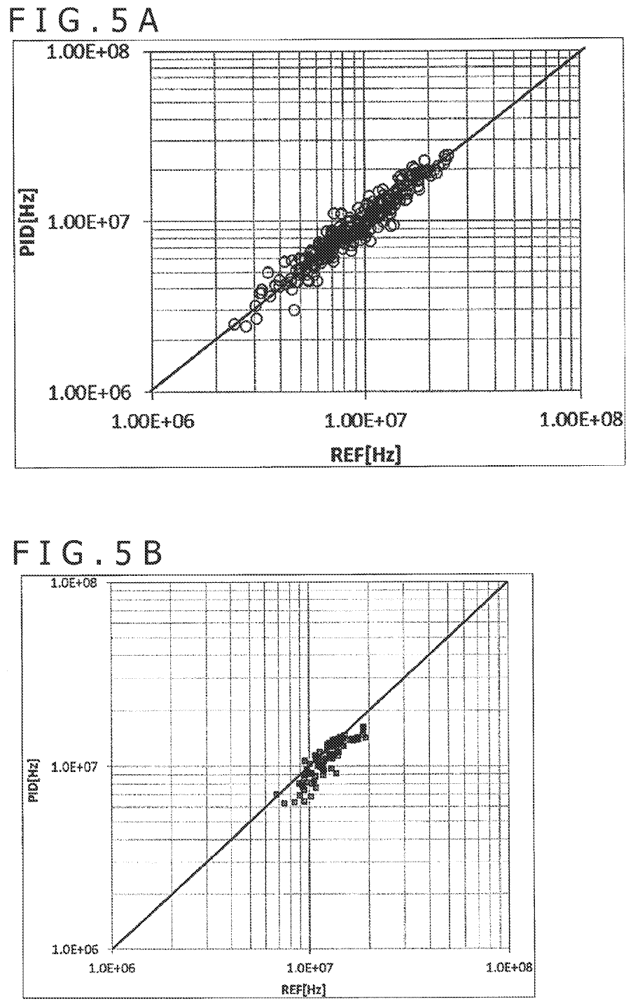

FIGS. 5A and 5B each present an example of a PID detection result obtained by the semiconductor device 10. In each of FIGS. 5A and 5B, a vertical axis represents an oscillation frequency (expressed as PID) in a case of connection of the measurement transistor 111 to the oscillation circuit 130, and a horizontal axis represents an oscillation frequency (expressed as REF) in a case of connection of the reference transistor 110 to the oscillation circuit 130 for a comparison between these frequencies. FIG. 5A is a graph representing a detection result obtained in a case where PID is reduced by a protection element provided at the gate of the measurement transistor 111, while FIG. 5B is a graph representing a detection result obtained in a case where PID is intentionally caused by a plasma process.

As apparent from FIG. 5A, in the case where PID in the measurement transistor 111 is reduced by the protection element, the oscillation frequency of the oscillation circuit 130 to which the measurement transistor 111 is connected is substantially equivalent to the oscillation frequency of the oscillation circuit 130 to which the reference transistor 110 is connected. On the other hand, as apparent from FIG. 5B, in the case where PID has been caused in the measurement transistor 111, the oscillation frequency of the oscillation circuit 130 to which the measurement transistor 111 is connected is lower than the oscillation frequency of the oscillation circuit 130 to which the reference transistor 110 is connected.

Accordingly, the semiconductor device 10 is capable of detecting the presence or absence of PID in the measurement transistor 111 as a change of the oscillation frequency of the oscillation circuit 130.

### (1.3. Superiority of Semiconductor Device)

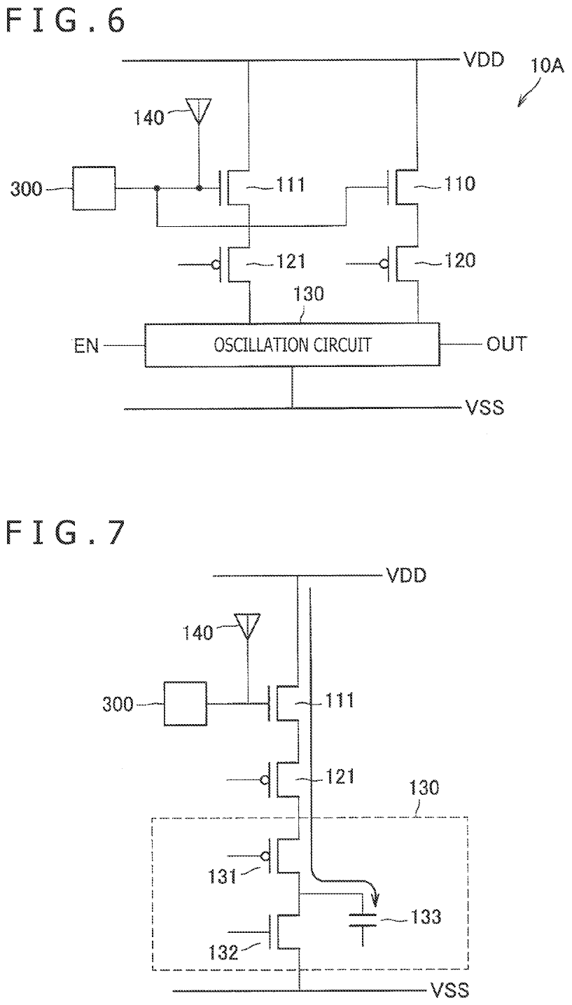

Superiority of the semiconductor device 10 according to the present embodiment will herein be described with reference to a semiconductor device 10A according to a comparative example depicted in FIGS. 6 and 7. FIG. 6 is a circuit diagram explaining a structure example of the semiconductor device according to the comparative example, while FIG. 7 is a circuit diagram depicting an extracted configuration between a VDD wire and a VSS wire of the semiconductor device according to the comparative example.

As depicted in FIG. 6, the measurement transistor 111 the gate of which is electrically connected to the antenna unit 140, and the selection transistor 121 are provided in series between the VDD wire or the VSS wire and the oscillation circuit 130 in the semiconductor device 10A according to the comparative example. Further, the reference transistor 110 the gate of which is not electrically connected to the antenna unit, and the reference selection transistor 120 are provided in series between the VDD wire or the VSS wire and the oscillation circuit 130 and in parallel to the measurement transistor 111 and the selection transistor 121 in the semiconductor device 10A. Note that a PAD 300 for external input is provided at the gates of the measurement transistor 111 and the reference transistor 110. The measurement transistor 111 and the reference transistor 110 are brought into an on-state in response to an input from the PAD 300. Even the semiconductor device 10A having such a structure is capable of controlling electric connection between the measurement transistor 111 and the oscillation circuit 130, by controlling the on-state or the off-state of the selection transistor 121. In such a manner, the semiconductor device 10A is capable of changing the voltage applied to the oscillation circuit 130, according to the threshold voltage Vth of the measurement transistor 111.

Specifically, as depicted in FIG. 7, the measurement transistor 111 the gate of which is electrically connected to the antenna unit 140, the selection transistor 121, and the P-type transistor 131 and the N-type transistor 132 included in one inverter in the oscillation circuit 130 are provided in series between the VDD wire and the VSS wire in the semiconductor device 10A. Further, the load capacitance 133 is electrically connected to the output side of the inverter.

Assuming herein that the capacitance of the load capacitance 133 is C, that the channel resistance of the measurement transistor 111 is R1, that the channel resistance of the selection transistor 121 is R3, and that the channel resistance of the P-type transistor 131 is R2, the charging time t of the load capacitance 133 can be expressed by the following Equation (3).

t=(R1+R3+R2)×C (3)

Accordingly, assuming that the oscillation circuit 130 is a ring oscillator to which N (N represents an odd number) inverters are connected, an oscillation frequency f of the oscillation circuit 130 can be expressed by the following Equation (4).

$$\begin{matrix}f = 1 / ( 2 \times N \times t ) \\ = 1 / \{ 2 \times N \times ( R 1 + R 3 + R 2 ) \times C \}\end{matrix} \qquad ( 4 )$$

It is apparent from the Equation (2) and the Equation (4) that not only the channel resistance R1 of the measurement transistor 111 and the channel resistance R2 of the P-type transistor but also the channel resistance R3 of the selection transistor 121 affects the oscillation frequency of the oscillation circuit 130 in the semiconductor device 10A according to the comparative example. It is therefore understood that a change amount of the oscillation frequency corresponding to a change amount of the channel resistance R1 of the measurement transistor 111 decreases in the semiconductor device 10A in comparison with that amount of the semiconductor device 10 according to the present embodiment. Accordingly, there is a possibility that PID detection accuracy of the semiconductor device 10A is lowered by an error factor corresponding to the channel resistance R3 of the selection transistor 121 in comparison with the semiconductor device 10 according to the present embodiment.

Incidentally, it is considered that an increase in a channel width of the selection transistor 121 can reduce the channel resistance R3 of the selection transistor 121 to an ignorable level. In such a case, however, an area of the semiconductor device 10A becomes larger according to an increase in an occupied area of the selection transistor 121. This enlargement of the area of the semiconductor device 10A is not preferable because the semiconductor device 10A is provided inside a semiconductor device which executes predetermined functions, for management of a manufacturing process.

Specifically, in a case where the selection transistor 121, the measurement transistor 111, the P-type transistor 131, and the N-type transistor 132 each have an area S in a configuration where the oscillation circuit 130 includes 101 inverters, the area of the semiconductor device 10A is expressed by the following Equation (5) when areas of the antenna unit 140 and the wire are ignored.

4×S+101×2×S=206×S (5)

Particularly in a case where the multiple measurement transistors 111 each having a different antenna ratio are connected to the oscillation circuit 130, the selection transistor 121 is provided for each of the multiple measurement transistors 111. For example, in a case where the 101 measurement transistors 111 each having a different antenna ratio are connected to the 101 inverters of the oscillation circuit 130 with one-to-one correspondence, the area of the semiconductor device 10A is expressed by the following Equation (6).

2×101×S+2×101×S=404×S (6)

On the other hand, in a case where the channel width of the selection transistor 121 is made 100 times larger to reduce the channel resistance R3 of the selection transistor 121 to an ignorable level (to reduce the channel resistance to 1/100, for example), the area of the semiconductor device 10A is expressed by the following Equation (7).

2×S+100×2×S+101×2×S=404×S (7)

Further, in a case where the 101 measurement transistors 111 each having a different antenna ratio are connected to the 101 inverters of the oscillation circuit 130 with one-to-one correspondence, the area of the semiconductor device 10A is expressed by the following Equation (8).

101×S+101×100×S+2×101×S=10403×S (8)

Accordingly, a considerable increase in the occupied area is needed to improve PID detection accuracy of the semiconductor device 10A according to the comparative example. On the other hand, the channel resistance of the selection transistor 121 does not affect the oscillation frequency of the oscillation circuit 130 in the semiconductor device 10 according to the present embodiment. Accordingly, PID detection accuracy can be improved without a considerable increase in the occupied area.

In the semiconductor device 10 according to the present embodiment, the selection transistor 121 is provided in parallel to the antenna unit 140 on the gate side of the measurement transistor 111. In such a case, it is possible that the channel resistance R3 of the selection transistor 121 does not affect the oscillation frequency f. Further, according to the semiconductor device 10, the measurement transistor 111 and the reference transistor 110 are connected to the same oscillation circuit 130 in parallel. In such a case, the semiconductor device 10 is capable of minimizing an error factor produced by the channel resistance R2 of the P-type transistor 131. Accordingly, the semiconductor device 10 is capable of increasing the change amount of the oscillation frequency f corresponding to the change amount of the channel resistance R1 of the measurement transistor 111 without increasing the occupied area, and is therefore capable of improving PID detection accuracy.

### (1.4. Modifications)

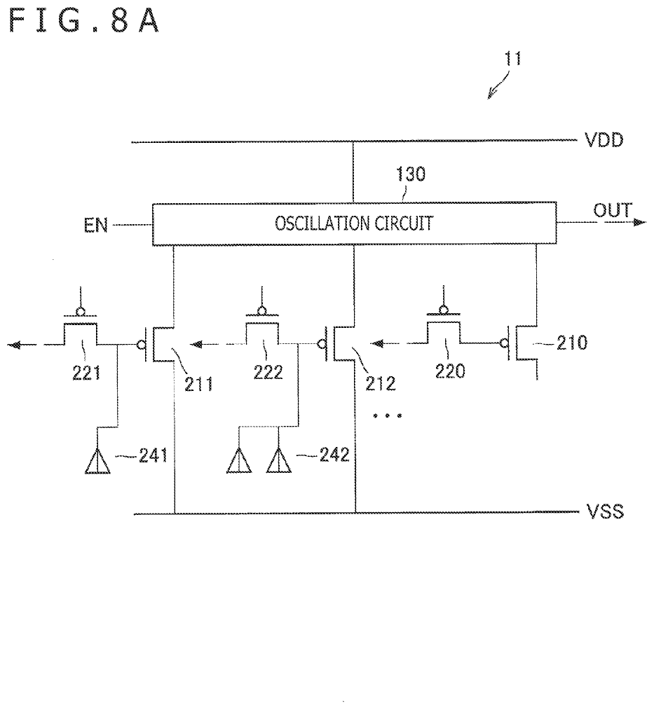

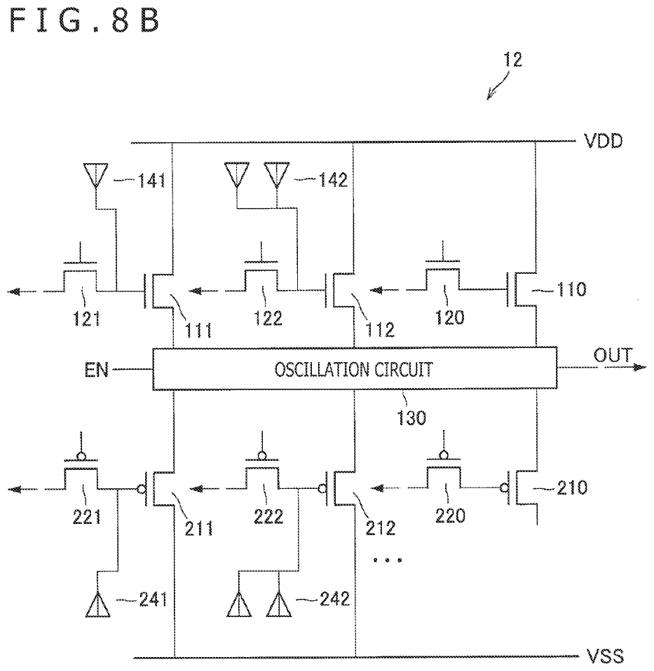

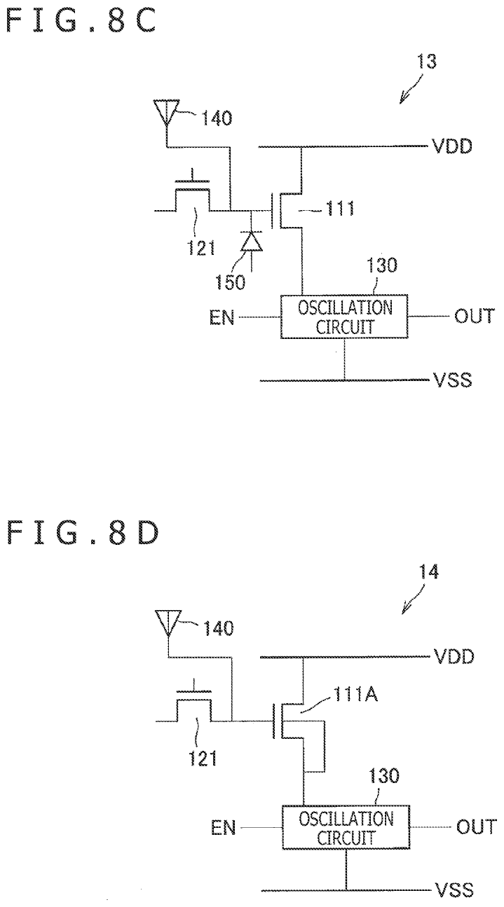

Modifications of the semiconductor device 10 according to the present embodiment will subsequently be described with reference to FIGS. 8A to 8D. FIGS. 8A to 8D are circuit diagrams presenting structure examples of semiconductor devices according to first to fourth modifications.

### (First Modification)

As depicted in FIG. 8A, a semiconductor device 11 according to a first modification includes a plurality of measurement transistors 211 and 212 gates of which are electrically connected to antenna units 241 and 242, respectively, a plurality of selection transistors 221 and 222 sources of which are electrically connected to the gates of the measurement transistors 211 and 212, respectively, a reference transistor 210, a reference selection transistor 220 a source of which is electrically connected to a gate of the reference transistor 210, and the oscillation circuit 130 electrically connected to sources of the plurality of measurement transistors 211 and 212 and the reference transistor 210.

A set of the antenna unit 241 and the measurement transistor 211 and a set of the antenna unit 242 and the measurement transistor 212 are each provided so as to have a different area ratio (i.e., antenna ratio) of the gate of the measurement transistor to the antenna unit. Note that the semiconductor device 11 according to the first modification may further include an antenna unit and a measurement transistor having a different antenna ratio.

According to the semiconductor device 11 of the first modification, the measurement transistors 211 and 212, the selection transistors 221 and 222, the reference transistor 210, and the reference selection transistor 220 are provided on the VSS wire side with respect to the oscillation circuit 130. The semiconductor device 11 configured as above is capable of detecting occurrence of PID even in the FET provided on the VSS wire side with respect to the oscillation circuit 130.

Further, the measurement transistors 211 and 212, the selection transistors 221 and 222, the reference transistor 210, and the reference selection transistor 220 may each be provided as a P-type transistor. According to such a configuration, the semiconductor device 11 is capable of further increasing a change of the oscillation frequency of the oscillation circuit 130 produced according to a change of the threshold voltage Vth of each of the measurement transistors 211 and 212.

### (Second Modification)

As depicted in FIG. 8B, a semiconductor device 12 according to a second modification includes a plurality of measurement transistors 111, 112, 211, and 212 gates of which are electrically connected to antenna units 141, 142, 241, and 242, respectively, a plurality of selection transistors 121, 122, 221, and 222 sources of which are electrically connected to the gates of the measurement transistors 111, 112, 211, and 212, respectively, reference transistors 110 and 210, reference selection transistors 120 and 220 sources of which are electrically connected to gates of the reference transistors 110 and 210, respectively, and the oscillation circuit 130 electrically connected to sources of the plurality of measurement transistors 111, 112, 211, and 212 and the reference transistors 110 and 210.

A set of the antenna unit 141 and the measurement transistor 111 and a set of the antenna unit 142 and the measurement transistor 112 are each provided so as to have a different antenna ratio. A set of the antenna unit 241 and the measurement transistor 211 and a set of the antenna unit 242 and the measurement transistor 212 are each provided so as to have a different antenna ratio. Note that the semiconductor device 12 according to the second modification may further include an antenna unit and a measurement transistor having a different antenna ratio on each of the VDD wire side and the VSS wire side.

According to the semiconductor device 12 of the second modification, the measurement transistors 111 and 112, the selection transistors 121 and 122, the reference transistor 110, and the reference selection transistor 120 are provided on the VDD wire side with respect to the oscillation circuit 130. The measurement transistors 211 and 212, the selection transistors 221 and 222, the reference transistor 210, and the reference selection transistor 220 are provided on the VSS wire side with respect to the oscillation circuit 130. In such a case, the semiconductor device 12 is capable of detecting the presence or absence of PID in the FET provided on each of the VDD wire side and the VSS wire side with respect to the oscillation circuit 130. Specifically, the semiconductor device 12 is capable of detecting the presence or absence of PID of the measurement transistors 111 and 112 on the VDD wire side, by using an undepicted switch to electrically connect the VDD wire and the oscillation circuit 130. Further, the semiconductor device 12 is capable of detecting the presence or absence of PID of the measurement transistors 211 and 212 on the VSS wire side, by using an undepicted switch to electrically connect the VSS wire and the oscillation circuit 130.

Further, the measurement transistors 111 and 112, the selection transistors 121 and 122, the reference transistor 110, and the reference selection transistor 120 that are provided on the VDD wire side may each be provided as an N-type transistor. On the other hand, the measurement transistors 211 and 212, the selection transistors 221 and 222, the reference transistor 210, and the reference selection transistor 220 that are provided on the VSS wire side may each be provided as a P-type transistor. According to such a configuration, the semiconductor device 12 is capable of further increasing a change of the oscillation frequency of the oscillation circuit 130 produced according to a change of the threshold voltage Vth of each of the measurement transistors 111, 112, 211, and 212.

### (Third Modification)

As depicted in FIG. 8C, a semiconductor device 13 according to a third modification includes the measurement transistor 111 the gate of which is electrically connected to the antenna unit 140, the selection transistor 121 the source of which is electrically connected to the gate of the measurement transistor 111, a protection element 150 electrically connected to the gate of the measurement transistor 111, a reference transistor (not depicted), a reference selection transistor (not depicted) a source of which is electrically connected to a gate of the reference transistor, and the oscillation circuit 130 electrically connected to the sources of the measurement transistor 111 and the reference transistor.

The protection element 150 is a circuit element which has a high resistance value at a current or a voltage within a predetermined range and has a low resistance value at a current or a voltage of a threshold or in excess of the threshold. In a case where a predetermined amount of charges or larger are accumulated in the antenna unit 140 during a plasma process, a resistance value of the protection element 150 is lowered, thereby releasing accumulated charges. In such a manner, the protection element 150 can reduce PID caused in the measurement transistor 111. For example, the protection element 150 may be any of various types of semiconductor diodes.

Accordingly, the semiconductor device 12 according to the third modification can evaluate a PID reduction effect of the protection element 150 by a comparison between the measurement transistor 111 including the protection element 150 and a measurement transistor not including the protection element 150.

Further, the protection element 150 may be electrically connected to the gate of the measurement transistor 111 through a wire provided in a layer located above the antenna unit 140. In such a case, the protection element 150 is not electrically connected to the measurement transistor 111 during a plasma process where the antenna unit 140 functions as an antenna. Accordingly, the antenna unit 140 causes PID in the measurement transistor 111. Thereafter, the protection element 150 is electrically connected to the gate of the measurement transistor 111 through a wire provided in a layer located above the antenna unit 140. In such a manner, the protection element 150 is capable of reducing PID caused by a wire or a via functioning as an antenna and located in a layer above the antenna unit 140.

According to such a configuration, the protection element 150 is capable of reducing PID caused in the measurement transistor 111 by the via or the wire located in the layer above the antenna unit 140. In such a case, PID can be caused in the measurement transistor 111 only by the antenna unit 140. Accordingly, the semiconductor device 13 is capable of evaluating an effect of PID caused in the measurement transistor 111 by the antenna unit 140, with higher accuracy.

### (Fourth Modification)

As depicted in FIG. 8D, a semiconductor device 14 according to a fourth modification includes a measurement transistor 111A a gate of which is electrically connected to the antenna unit 140, the selection transistor 121 the source of which is electrically connected to the gate of the measurement transistor 111, the protection element 150 electrically connected to the gate of the measurement transistor 111, a reference transistor (not depicted), a reference selection transistor (not depicted) a source of which is electrically connected to a gate of the reference transistor, and the oscillation circuit 130 electrically connected to sources of the measurement transistor 111 and the reference transistor.

According to the semiconductor device 14 of the fourth modification, a body terminal of the measurement transistor 111A is electrically connected to a source side wire of the measurement transistor 111A. Generally, a body terminal of a transistor is electrically connected to the VDD wire or the VSS wire. However, the body terminal of the transistor can also be electrically connected to a source side wire of the transistor. The semiconductor device 14 according to the fourth modification is capable of detecting the presence or absence of PID caused by the antenna unit 140, and evaluating a level of PID even in the measurement transistor 111A thus configured. In a case where a body and a source of the measurement transistor 111A are electrically connected, the measurement transistor 111A is provided on an N-type substrate. In a case where the measurement transistor 111A is provided on a P-type substrate, short-circuiting between the source and the body is prevented by forming a deep well region where N-type doping reaches a deep region.

### (1.5. Operation Example)

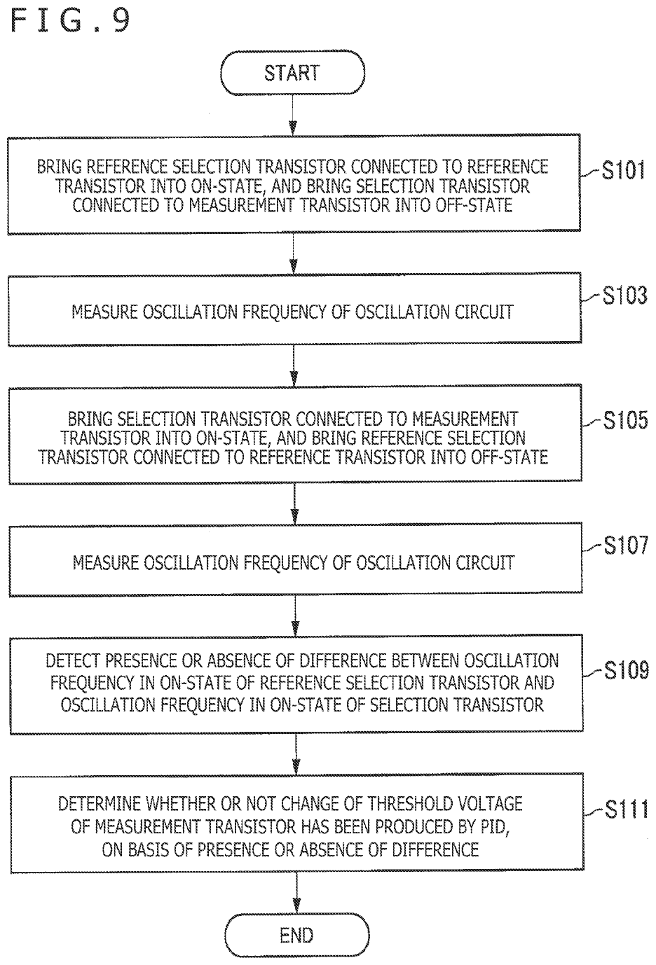

An operation example of the semiconductor device 10 according to the present embodiment will subsequently be described with reference to FIG. 9. FIG. 9 is a flowchart presenting an example of the operation of the semiconductor device 10 according to the present embodiment.

First, as presented in FIG. 9, the reference selection transistor 120 electrically connected to the gate of the reference transistor 110 is brought into an on-state, and the selection transistor 121 electrically connected to the gate of the measurement transistor 111 is brought into an off-state (S101). Accordingly, the reference transistor 110 is electrically connected to the oscillation circuit 130.

Subsequently, an oscillation frequency of the oscillation circuit 130 is measured (S103). Accordingly, an oscillation frequency of the oscillation circuit 130 in a case of connection of a transistor where no PID is caused is measured.

Thereafter, the selection transistor 121 electrically connected to the gate of the measurement transistor 111 is brought into an on-state, and the reference selection transistor 120 electrically connected to the gate of the reference transistor 110 is brought into an off-state (S105). Accordingly, the measurement transistor 111 is electrically connected to the oscillation circuit 130.

Then, an oscillation frequency of the oscillation circuit 130 is measured (S107). Accordingly, an oscillation frequency of the oscillation circuit 130 in a case of connection of a transistor where PID has been caused is measured.

Subsequently, detected is the presence or absence of a difference between an oscillation frequency of the oscillation circuit 130 in a case of connection of the reference transistor 110 and an oscillation frequency of the oscillation circuit 130 in a case of connection of the measurement transistor 111 (S109).

Thereafter, it is determined whether or not a change of the threshold voltage Vth of the measurement transistor 111 has been produced by PID, on the basis of the detected difference of the oscillation frequency (S111). For example, in a case where the detected difference of the oscillation frequency is a predetermined value or larger, it may be determined that the change of the oscillation frequency has resulted from a change of the threshold voltage Vth of the measurement transistor 111 produced by PID.

It can be easily determined, by using the semiconductor device 10 according to the present embodiment, whether or not PID has been caused by the antenna unit 140 of the semiconductor device 10 or whether or not the threshold voltage of the measurement transistor 111 has been changed by PID of the antenna unit 140.

### (1.6. Application Examples)

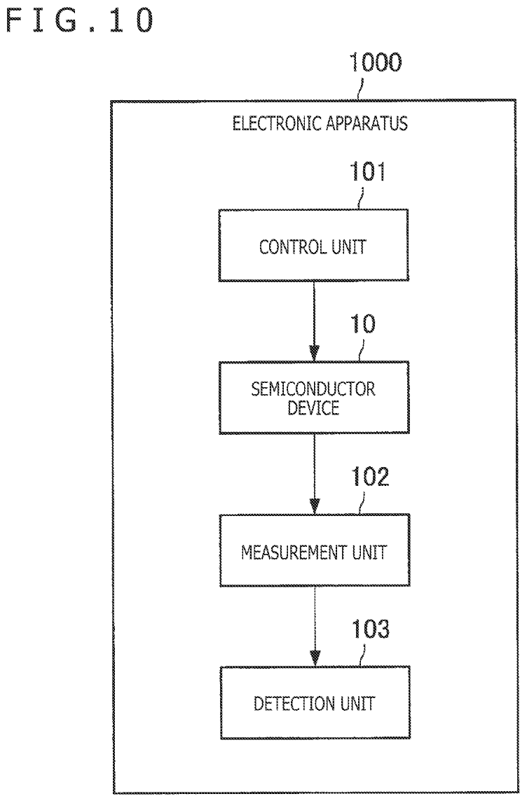

An example of the semiconductor device 10 according to the present embodiment applied to an electronic apparatus will subsequently be described with reference to FIGS. 10 to 12. FIGS. 10 to 12 are block diagrams depicting configurations of electronic apparatuses according to first to third application examples.

### (First Application Example)

As depicted in FIG. 10, an electronic apparatus 1000 according to the first application example includes a control unit 101, the semiconductor device 10, a measurement unit 102, and a detection unit 103. Note that a part of or all the control unit 101, the measurement unit 102, and the detection unit 103 may be provided inside the semiconductor device 10.

The control unit 101 controls electric connection of the measurement transistor 111 and the reference transistor 110 with the oscillation circuit 130, by controlling the on-state or the off-state of each of the selection transistor 121 and the reference selection transistor 120 of the semiconductor device 10. Further, the control unit 101 controls electric connection of the multiple antenna units 140 and the multiple measurement transistors 111 each having a different antenna ratio with the oscillation circuit 130, by controlling the on-state or the off-state of the selection transistor 121 of the semiconductor device 10.

The semiconductor device 10 causes the oscillation circuit 130 that is electrically connected to each of the multiple measurement transistors 111 having antenna ratios different from one another or electrically connected to the reference transistor 110, to output an alternating current output. The oscillation frequency of the alternating current output from the oscillation circuit 130 changes according to the channel resistance of each of the multiple measurement transistors 111 or the reference transistor 110 electrically connected to the oscillation circuit 130. In such a manner, the semiconductor device 10 can convert a channel resistance difference of each of the multiple measurement transistors 111 having antenna ratios different from one another or a channel resistance difference of the reference transistor 110, into a change of the oscillation frequency of the oscillation circuit 130.

The measurement unit 102 measures the oscillation frequency of the alternating current output received from the oscillation circuit 130 of the semiconductor device 10. The measurement unit 102 may be a measurement circuit provided inside the semiconductor device 10 or the electronic apparatus 1000, or may be a tester provided outside the electronic apparatus 1000.

The detection unit 103 detects the presence or absence of an oscillation frequency difference on the basis of the oscillation frequency of the oscillation circuit 130 measured by the measurement unit 102. Specifically, the detection unit 103 compares an oscillation frequency of the oscillation circuit 130 to which the reference transistor 110 is connected, and an oscillation frequency of the oscillation circuit 130 to which the measurement transistor 111 is connected. At this time, the detection unit 103 detects the presence of an oscillation frequency difference in a case where the oscillation frequency of the oscillation circuit 130 to which the measurement transistor 111 is connected has changed from the oscillation frequency of the oscillation circuit 130 to which the reference transistor 110 is connected. In addition, the detection unit 103 may detect that PID has been caused in the electronic apparatus 1000.

As apparent from above, the electronic apparatus 1000 according to the first application example requires only a smaller area and a smaller number of terminals to detect whether or not PID has been caused in internal transistors by using the semiconductor device 10. Accordingly, the semiconductor device 10 is capable of reducing step management costs of the electronic apparatus 1000 according to the first application example.

### (Second Application Example)

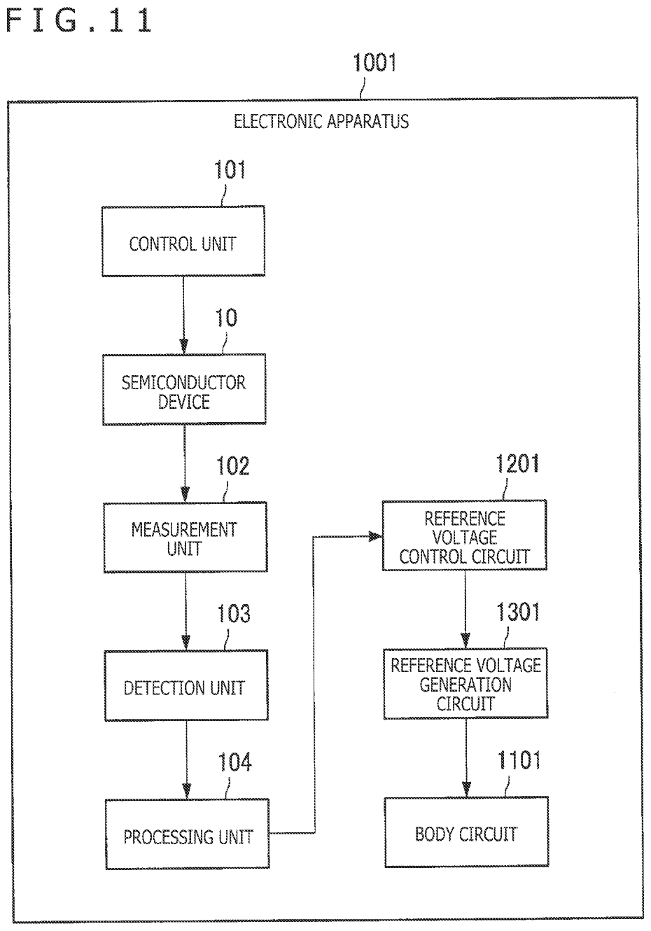

As depicted in FIG. 11, an electronic apparatus 1001 according to the second application example includes the control unit 101, the semiconductor device 10, the measurement unit 102, the detection unit 103, a processing unit 104, a reference voltage control circuit 1201, a reference voltage generation circuit 1301, and a body circuit 1101. Note that a part of or all the control unit 101, the measurement unit 102, and the detection unit 103 may be included inside the semiconductor device 10.

The control unit 101, the semiconductor device 10, the measurement unit 102, and the detection unit 103 are similar to those described in the first application example, and are therefore not repeatedly described herein.

The processing unit 104 determines a process for reducing an effect produced by PID, on the basis of the presence or absence of PID. According to the second application example, in a case where PID has been caused, the processing unit 104 outputs an instruction for increasing a reference voltage to be supplied to the body circuit 1101 which executes functions of the electronic apparatus 1001. The threshold voltage Vth of the transistor increases in a case where PID has been caused. Accordingly, at a reference voltage set at the time of design of the electronic apparatus 1001, the transistor may not be brought into an on-state, or a current flowing in the transistor may decrease. Therefore, the processing unit 104 gives an instruction for increasing the reference voltage to be supplied to the body circuit 1101 to achieve driving of the body circuit 1101 similarly to a case where PID has not been caused.

The reference voltage control circuit 1201 controls a reference voltage generated by the reference voltage generation circuit 1301, according to the instruction received from the processing unit 104. Specifically, the reference voltage control circuit 1201 controls the reference voltage generation circuit 1301 such that the reference voltage to be supplied to the body circuit 1101 increases according to the instruction received from the processing unit 104. For example, the reference voltage control circuit 1201 may control the reference voltage generation circuit 1301 such that the reference voltage increases by using a fuse or trimming.

The reference voltage generation circuit 1301 generates a reference voltage to be supplied to the body circuit 1101. Specifically, the reference voltage generation circuit 1301 is a power source circuit which generates a reference voltage having a voltage value corresponding to the control by the reference voltage control circuit 1201. For example, the reference voltage generation circuit 1301 may generate a reference voltage raised to a value sufficient for cancelling a change of the threshold voltage Vth of the transistor produced by PID, on the basis of the control by the reference voltage control circuit 1201.

The body circuit 1101 is a main circuit which drives at a reference voltage supplied from the reference voltage generation circuit 1301 and executes functions of the electronic apparatus 1001. The voltage value of the reference voltage supplied from the reference voltage generation circuit 1301 is controlled on the basis of the presence or absence of PID. Accordingly, the body circuit 1101 achieves smooth driving regardless of the presence or absence of PID.

Accordingly, the electronic apparatus 1001 according to the second application example is capable of reducing an effect resulting from PID by controlling the reference voltage to be supplied to the body circuit 1101.

### (Third Application Example)

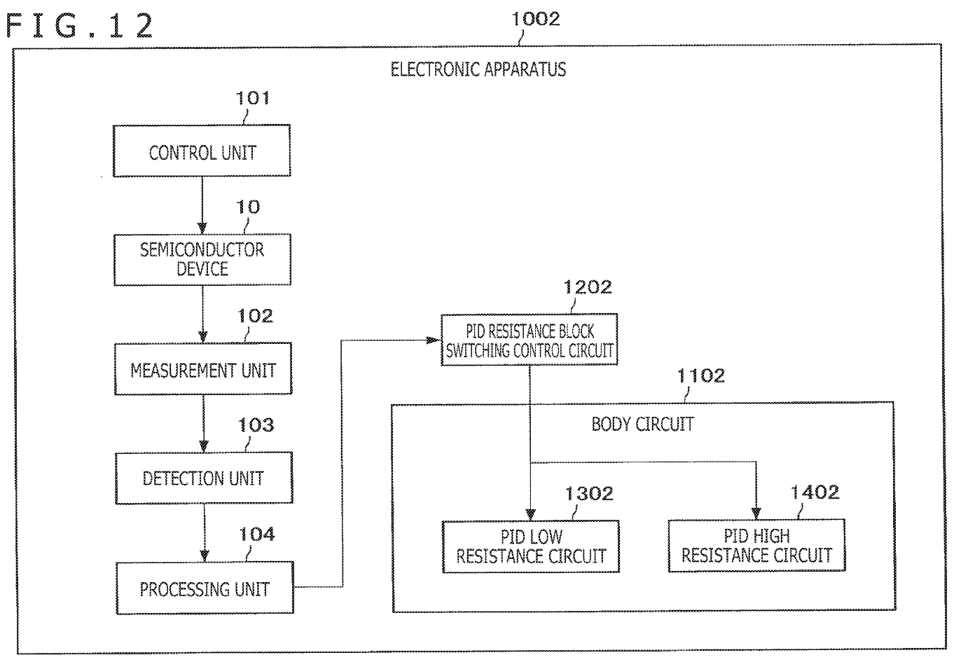

As depicted in FIG. 12, an electronic apparatus 1002 according to the third application example includes the control unit 101, the semiconductor device 10, the measurement unit 102, the detection unit 103, the processing unit 104, a PID resistance block switching control circuit 1202, and a body circuit 1102 including a PID low resistance circuit 1302 and a PID high resistance circuit 1402. Note that a part of or all the control unit 101, the measurement unit 102, and the detection unit 103 may be included inside the semiconductor device 10.

The control unit 101, the semiconductor device 10, the measurement unit 102, and the detection unit 103 are similar to those described in the first application example, and are therefore not repeatedly described herein.

The processing unit 104 determines a process for reducing an effect produced by PID, on the basis of the presence or absence of PID. According to the third application example, in a case where PID has been caused, the processing unit 104 outputs an instruction for switching the PID low resistance circuit 1302 executing a function to the PID high resistance circuit 1402 to execute the same function in the body circuit 1102. The threshold voltage Vth of the transistor increases in a case where PID has been caused. Accordingly, at a reference voltage set at the time of design of the electronic apparatus 1002, the transistor may not be brought into an on-state, or a current flowing in the transistor may decrease. The processing unit 104 therefore gives an instruction for performing a process of switching to the PID high resistance circuit 1402 which is unlikely to be affected by PID, instead of using the PID low resistance circuit 1302 which is considerably affected by PID in the body circuit 1102.

The PID resistance block switching control circuit 1202 controls switching of connection between the PID low resistance circuit 1302 and the PID high resistance circuit 1402 within the body circuit 1102 according to the instruction received from the processing unit 104. Specifically, the PID resistance block switching control circuit 1202 switches circuit connection from the PID low resistance circuit 1302 to the PID high resistance circuit 1402 according to the instruction received from the processing unit 104. For example, the PID resistance block switching control circuit 1202 may switch connection with the circuits within the body circuit 1102 from the PID low resistance circuit 1302 to the PID high resistance circuit 1402 by using a fuse or a switching element.

The body circuit 1102 is a main circuit which executes functions of the electronic apparatus 1001 and includes the PID low resistance circuit 1302 and the PID high resistance circuit 1402. The PID low resistance circuit 1302 and the PID high resistance circuit 1402 are a circuit group executing the same function. The circuit to be used is switched between the PID low resistance circuit 1302 and the PID high resistance circuit 1402 according to the presence or absence of PID. Specifically, in the body circuit 1102, the PID low resistance circuit 1302 is used in a case where PID has not been caused, and the PID high resistance circuit 1402 is used in a case where PID has been caused. In such a manner, the body circuit 1102 achieves smooth driving regardless of the presence or absence of PID.

Accordingly, the electronic apparatus 1002 according to the third application example is capable of reducing an effect resulting from PID by switching the use of the circuit group within the body circuit 1101.

### 2. Second Embodiment

### (2.1. Structure Example)

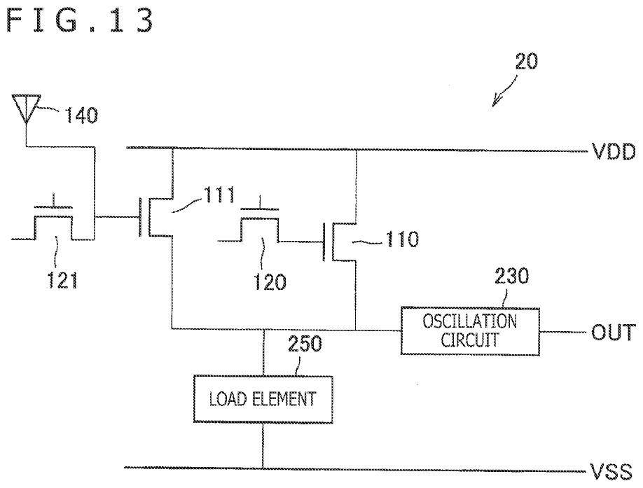

A structure example of a semiconductor device according to the second embodiment of the present disclosure will subsequently be described with reference to FIG. 13. FIG. 13 is a circuit diagram explaining the structure example of the semiconductor device according to the present embodiment.

As depicted in FIG. 13, a semiconductor device 20 according to the present embodiment includes the antenna unit 140, the selection transistor 121, the measurement transistor 111, the reference selection transistor 120, the reference transistor 110, a load element 250, and an oscillation circuit 230.

The semiconductor device 20 according to the second embodiment is different from the semiconductor device 10 according to the first embodiment in that the sources of the measurement transistor 111 and the reference transistor 110 are electrically connected to an input of the oscillation circuit 230 and the load element 250.

The load element 250 is an element which consumes power, and is provided to control a voltage input to the oscillation circuit 230. Specifically, the load element 250 is a passive element having a predetermined resistance and is provided between the VSS wire (or ground wire) and the sources of the measurement transistor 111 and the reference transistor 110. The load element 250 may be any type of passive element as long as the passive element has a predetermined resistance. For example, the load element 250 may be a resistance element or a load transistor.

The oscillation circuit 230 is a voltage control oscillation circuit capable of controlling an oscillation frequency according to a magnitude of an input voltage. The oscillation circuit 230 may be a voltage control type ring oscillator, for example.

According to the semiconductor device 20 of the second embodiment, a potential difference between the VDD wire and the VSS wire is divided on the basis of a channel resistance of the measurement transistor 111 or the reference transistor 110 and a resistance value of the load element 250. A voltage corresponding to the channel resistance of the measurement transistor 111 or the reference transistor 110 is input to the oscillation circuit 230. Specifically, the semiconductor device 20 is allowed to input a voltage corresponding to a change of the channel resistance of the measurement transistor 111 to the oscillation circuit 230 by parallel connection between the load element 250 having the predetermined resistance and the oscillation circuit 230. In such a manner, the semiconductor device 20 is capable of detecting a change of the channel resistance of the measurement transistor 111 as a change of the oscillation frequency of the oscillation circuit 230.

Note herein that the potential difference between the VDD wire and the VSS wire is shared by the measurement transistor 111 and the oscillation circuit 130 in the semiconductor device 10 according to the first embodiment. Accordingly, in a case where the potential difference between the VDD wire and the VSS wire is small, the voltage applied to the oscillation circuit 130 becomes excessively low. In such a case, the oscillation circuit 130 does not easily oscillate. Incidentally, it is considered that, in order to increase the oscillation frequency of the oscillation circuit 130, the configuration of the oscillation circuit 130 is simplified (for example, the number of inverters of the ring oscillator is reduced). In such a case, however, accuracy of the oscillation circuit 130 may be reduced.

Further, after a start of oscillation of the oscillation circuit 130 in the semiconductor device 10 according to the first embodiment, power starts to be consumed at the oscillation circuit 130 due to a parasitic capacitance. As a result, a voltage applied to the oscillation circuit 130 gradually increases. Accordingly, the semiconductor device 10 according to the first embodiment requires a long time until stabilization of the voltage applied to the oscillation circuit 130 and stabilization of the oscillation frequency of the oscillation circuit 130. In such a case, detection of the presence or absence of PID requires a long time.

On the other hand, the semiconductor device 20 according to the second embodiment controls the oscillation frequency of the oscillation circuit 230 according to the input voltage. Accordingly, all the potential difference between the VDD wire and the VSS wire is applicable to the oscillation circuit 230. Further, according to the semiconductor device 20, the voltage input to the oscillation circuit 230 is determined by the channel resistance of the measurement transistor 111 or the reference transistor 110 and by the resistance value of the load element 250. In such a case, the time required for stabilization of the voltage input to the oscillation circuit 230 is shortened. Accordingly, the semiconductor device 20 is capable of reducing the time required for detection of the presence or absence of PID.

### (2.2. Specific Example)

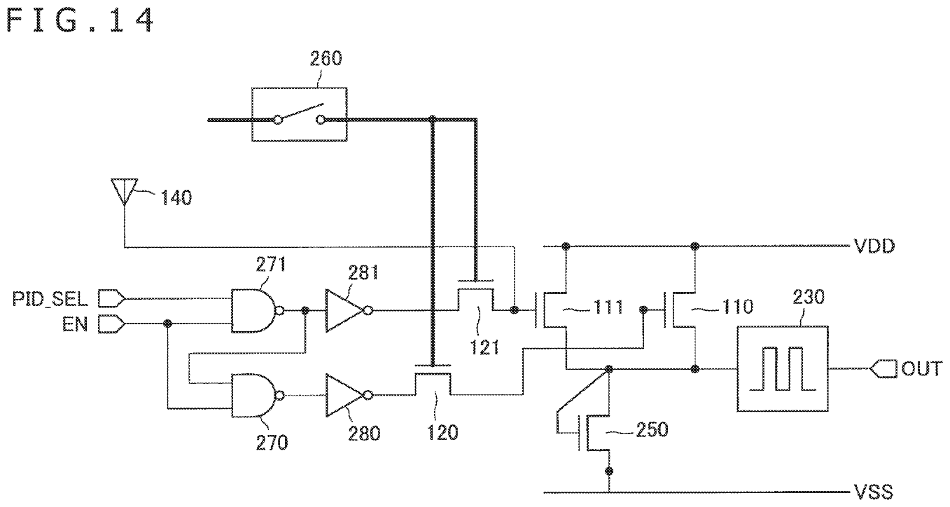

A more specific structure example of the semiconductor device 20 according to the present embodiment will subsequently be described with reference to FIGS. 14 and 15. FIG. 14 is a circuit diagram depicting a more specific circuit structure of the semiconductor device 20 according to the present embodiment, and FIG. 15 is a circuit diagram depicting a more specific circuit structure of the oscillation circuit 230.

For example, as depicted in FIG. 14, the semiconductor device 20 includes the measurement transistor 111 the gate of which is electrically connected to the antenna unit 140, and the reference transistor 110 the gate of which is not electrically connected to the antenna unit.

The sources of the measurement transistor 111 and the reference transistor 110 are connected in parallel to the load element 250 including a load transistor, and the oscillation circuit 230 serving as a voltage control type ring oscillator. In such a manner, a potential difference between the VDD wire and the VSS wire is applied to the oscillation circuit 230. Further, a divided voltage corresponding to the channel resistance of the measurement transistor 111 or the reference transistor 110 is input to the oscillation circuit 230. Accordingly, an alternating current at an oscillation frequency corresponding to the channel resistance is output.

Specifically, the oscillation circuit 230 may have a circuit structure depicted in FIG. 15. For example, the oscillation circuit 230 is a ring oscillator to which an odd number (e.g., 101 or the like) of NOT gates (inverters) are connected in a ring shape. The oscillation circuit 230 is capable of applying a potential difference Vd between the VDD wire and the VSS wire and a potential difference based on an input voltage Vin to each of the internal NOT gates, by complimentarily using N-type transistors and P-type transistors. In such a manner, the oscillation circuit 230 is capable of controlling the oscillation frequency of the alternating current output on the basis of the magnitude of the input voltage.

The selection transistor 121 and the reference selection transistor 120 are electrically connected to the respective gates of the measurement transistor 111 and the reference transistor 110. A switch 260 as a common switch is electrically connected to the gates of the selection transistor 121 and the reference selection transistor 120. The gates of the selection transistor 121 and the reference selection transistor 120 are electrically connected to separate power sources through the switch 260. Further, logic circuits including NOT gates (inverters) 281 and 280 and NAND gates 271 and 270 are electrically connected to the sources or the drains of the selection transistor 121 and the reference selection transistor 120.

The logic circuits including the NOT gates 281 and 280 and the NAND gates 271 and 270 bring the measurement transistor 111 into an on-state through the selection transistor 121 in a case where a PID SEL terminal and an EN terminal are both H (High). In addition, the logic circuits bring the reference transistor 110 into an on-state through the reference selection transistor 120 in a case where the PID SEL terminal and the EN terminal are L (Low) and H (High), respectively. Further, the logic circuits bring each of the measurement transistor 111 and the reference transistor 110 into an off-state in a case where the EN terminal is L (low) regardless of whether the PID SEL terminal is H (High) or L (Low).

The semiconductor device 20 according to the present embodiment is capable of detecting the presence or absence of PID with high accuracy even in a case of a low power source voltage. Further, the semiconductor device 20 is capable of detecting the presence or absence of PID in a shorter time.

Note that the semiconductor device 20 according to the second embodiment is different from the semiconductor device 10 according to the first embodiment in that the sources of the measurement transistor 111 and the reference transistor 110 are electrically connected to the load element 250 and the input of the oscillation circuit 230. Accordingly, each of the modifications and application examples of the semiconductor device 10 described in the first embodiment is similarly applicable to the semiconductor device 20 according to the second embodiment.

### 3. Third Embodiment

According to the embodiments described above, the oscillation frequency f of the oscillation circuit 130 needs to be converted into a voltage value to obtain a change amount of the channel resistance R1 or the threshold voltage Vth produced by PID. For example, an approximate function such as an error function, a table value based on experimental data, or the like may be used as a method for converting the oscillation frequency f into the voltage value. However, this method is not limited to these examples.

For example, it is possible to adopt such a simpler and easier method that calculates a change amount of the channel resistance R1 or the threshold voltage Vth resulting from PID by multiplying, by a coefficient, a difference between the oscillation frequency f in a case of being affected by PID and the oscillation frequency f in a case of not being affected by PID. However, for obtaining the change amount by using linear approximation in such a manner, a voltage obtained from a source follower circuit including the measurement transistor 111 and the reference transistor 110 needs to be processed such that a linear region (also referred to a region allowing linear approximation) is used in frequency characteristics of the oscillation circuit 130.

Accordingly, in the present embodiment, a semiconductor device, a detection method, an electronic apparatus, and an electronic apparatus control method capable of achieving a simpler and easier method for converting the oscillation frequency f into a voltage value are described hereinafter by giving examples. Note that a circuit that processes a voltage in relation to the range allowing linear approximation will be referred to as an “adjustment circuit” in the following description.

### (3.1. Frequency Characteristics of Oscillation Circuit and Used Voltage Range)

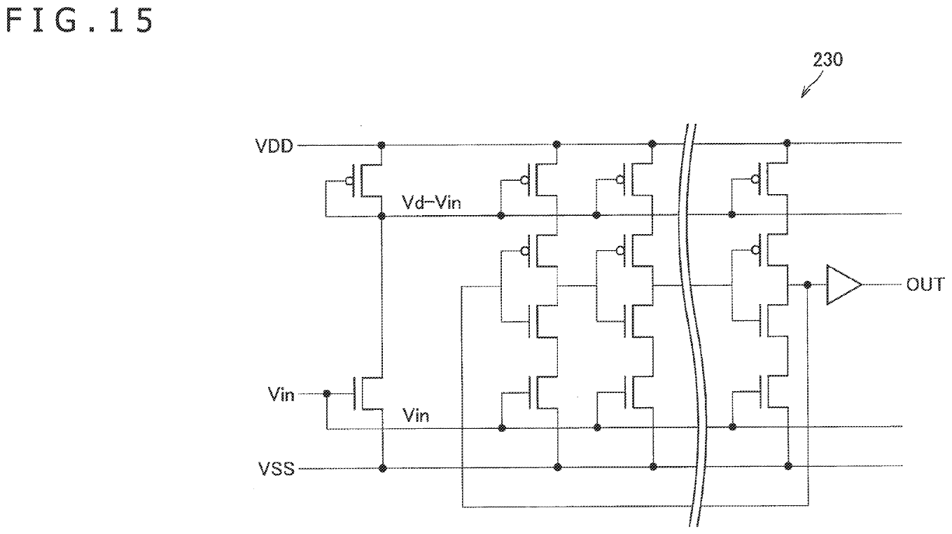

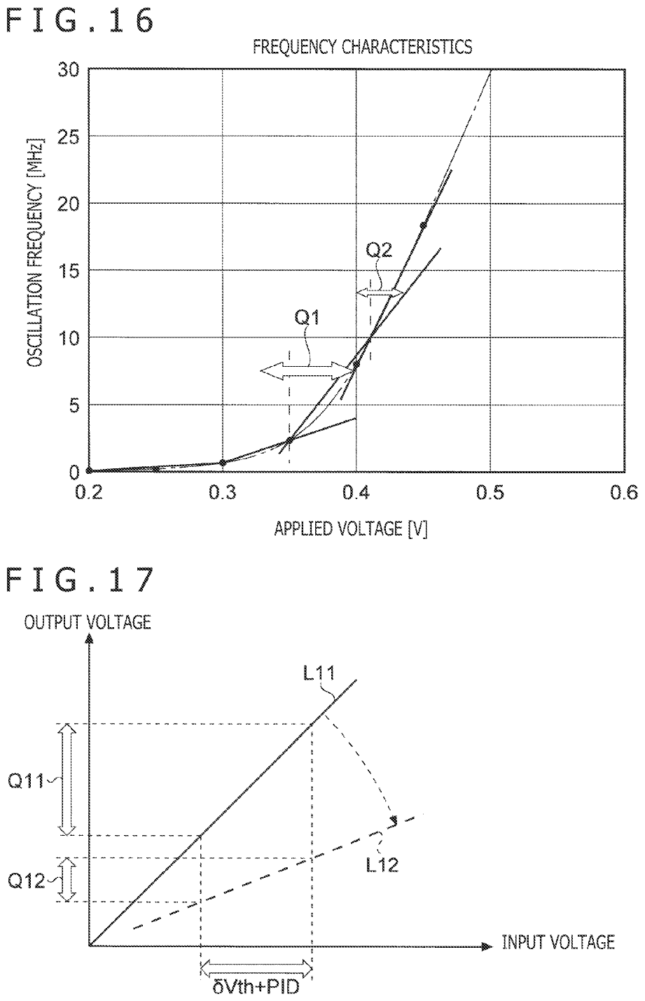

Before describing a semiconductor device including an adjustment circuit according to the present embodiment, frequency characteristics of an oscillation circuit and a voltage range used in the present embodiment will be described first. FIG. 16 is a graph presenting frequency characteristics of an oscillation circuit. As presented in FIG. 16, in a typical oscillation circuit, an oscillation frequency increases exponentially according to an increase in an applied voltage in a region of low voltage values (e.g., a region lower than 0.4 V in FIG. 16), and increases according to an increase in the applied voltage while maintaining a substantially fixed slope in a voltage region higher than the voltage region of low voltage values (e.g., a region ranging from 0.4 V (inclusive) to a predetermined voltage value (inclusive) in FIG. 16). While not presented in FIG. 16, linearity between the applied voltage and the oscillation frequency collapses in a region of high voltage values (e.g., a region of higher voltage values than the above predetermined voltage value). In this region, the oscillation frequency asymptotically approaches an upper limit value according to an increase in the applied voltage.

Assuming herein that manufacture variations (also expressed as δVth) of the threshold voltage Vth of a transistor incorporated in the semiconductor device is 20 mV and that a shift amount (also expressed as PID) of the threshold voltage Vth caused by PID is 50 mV, a range Q1 of variations of the threshold voltage Vth of the transistor included in the semiconductor device, that is, a used voltage range Q1, is 70 mV.

In such a case, assuming that a voltage Vout output from a source follower circuit including the measurement transistor 111 and the reference transistor 110 of the above embodiments has a value belonging to the low voltage range (e.g., 0.35 V), for example, the output voltage Vout considerably changes in a range where linearity is not secured. Accordingly, it is difficult to specify the oscillation frequency f of the oscillation circuit 130 only by multiplying a voltage Vin input to the source follower circuit by a fixed coefficient.

The present embodiment therefore narrows a change range of the output voltage Vout from the source follower circuit, by using an adjustment circuit. In such a manner, linearity of the oscillation frequency f for the voltage input to the oscillation circuit 130 (i.e., the output voltage Vout from the source follower circuit) increases. Accordingly, the oscillation frequency f of the oscillation circuit 130 can be specified by multiplying the input voltage Vin by a fixed coefficient.

For example, in FIG. 16, linearity of the oscillation frequency f for the output voltage Vout increases by narrowing the used voltage range Q1 to half of 70 mV, that is, 35 mV. Accordingly, accuracy of the oscillation frequency f obtained by multiplying the input voltage Vin by the coefficient can be improved.

Further, the adjustment circuit according to the present embodiment is allowed to have a function of shifting the change range of the output voltage Vout output from the source follower circuit. For example, the oscillation frequency f of the oscillation circuit 130 can be specified from the input voltage Vin more accurately by shifting the change range of the output voltage Vout to a range where linearity between the applied voltage and the oscillation frequency is secured (e.g., a region ranging from 0.4 V (inclusive) to the predetermined voltage value (inclusive) in FIG. 16), for example.

The range where linearity between the applied voltage and the oscillation frequency is secured is allowed to be used when a used voltage range Q2 is shifted to a range of 0.4 V (inclusive) to 0.435 mV (inclusive) in FIG. 16, for example. Accordingly, the oscillation frequency f can be specified more accurately by multiplying the input voltage Vin by the fixed coefficient.

### (3.2. Role of Adjustment Circuit)

As described above, the adjustment circuit according to the present embodiment is allowed to have both a role for limiting the change range of the output voltage Vout from the source follower circuit and a role for shifting the change range of the output voltage Vout to a desired range.

### (3.2.1. Limit of Voltage Change Range)

Limiting the change range of the output voltage Vout herein means adjusting voltage sensitivity of the source follower circuit. Specifically, as indicated by a straight line L11 in FIG. 17, a slope of the output voltage Vout output from the source follower circuit is usually proportional to the input voltage Vin input to a gate of a transistor included in the source follower circuit. Note that FIG. 17 is a graph representing a relation between an input voltage and an output voltage in the source follower circuit.

The present embodiment therefore provides an adjustment circuit to adjust voltage sensitivity of the source follower circuit. For example, as presented in FIG. 17, voltage sensitivity of the source follower circuit is adjusted such that the slope of the output voltage Vout with respect to the input voltage Vin has half the angle of a slope of the straight line L11 (corresponds to straight line L12). In such a case, the change range of the output voltage Vout with respect to the change range (δVth+PID) of the input voltage Vin can be reduced to a change range Q12 which is half the range of an original change range Q11. Accordingly, accuracy of the oscillation frequency f obtained by multiplying the input voltage Vin by the coefficient can be improved.

### (3.2.2. Shift of Used Voltage Range)

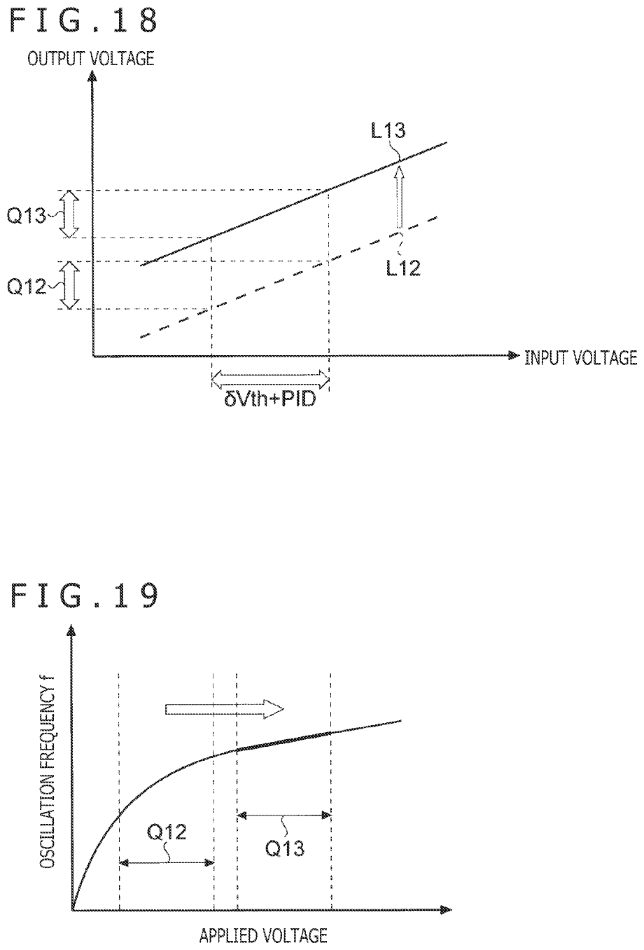

In addition, as described above, the adjustment circuit may further have a function of shifting the used voltage range in the present embodiment. FIG. 18 is a diagram explaining a shift of the used voltage range performed by the adjustment circuit according to the present embodiment, while FIG. 19 is a graph representing a relation between a change range and frequency characteristics before and after a shift performed by the adjustment circuit according to the present embodiment.

As presented in FIG. 19, the voltage input to the oscillation circuit 130 (output voltage Vout) can be shifted to a change range Q13 within a region where linearity of frequency characteristics is secured, by shifting the change range Q12 to the high voltage side as depicted in FIG. 18, for example. In such a manner, the oscillation frequency f of the oscillation circuit 130 can be specified from the input voltage Vin more accurately.

Note that the adjustment circuit according to the present embodiment is not required to include both the limiting function of the voltage change range of the source follower circuit and the shift function of the used voltage range, and is only required to have either one of these functions.

Further, while the case of shifting the change range Q12 in the low voltage region (e.g., the region lower than 0.4 V in FIG. 16) toward the high voltage side has been described by way of example, the shift in such a manner is not required to be adopted. The adjustment circuit can also be designed so as to shift a change range in a high voltage region (e.g., the region higher than the predetermined voltage value, which is mentioned in the description with reference to FIG. 16) toward the low voltage side.

### (3.3. Adjustment Circuit)

(3.3.1. Output Voltage Vout from Source Follower Circuit)

Next, before describing the adjustment circuit according to the present embodiment, the voltage (output voltage Vout) output from the source follower circuit and input to the oscillation circuit 130 in a case where the adjustment circuit is not provided will be described. Note that the output voltage from the source follower circuit will be referred to as “Vout0” and that the output voltage from the adjustment circuit will be referred to as “Vout1” for clarification in the present description.

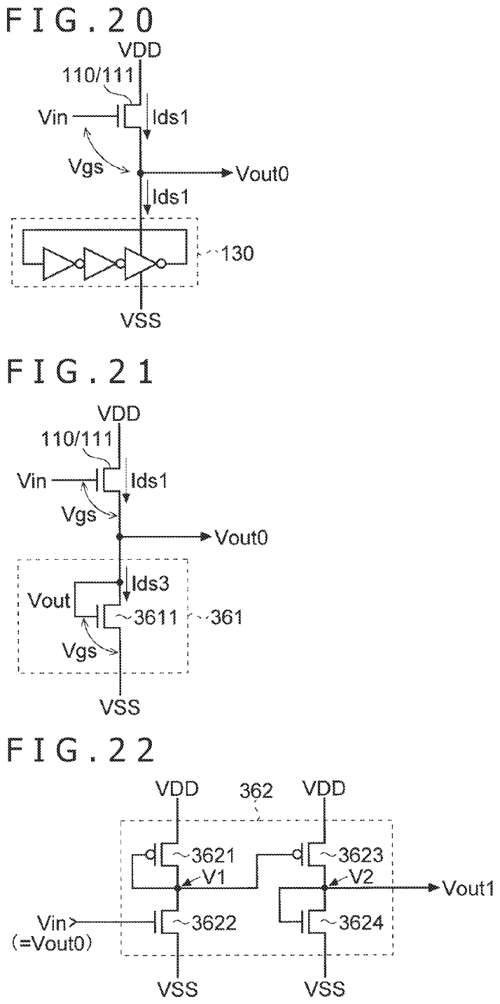

FIG. 20 is a diagram explaining the output voltage from the source follower circuit. As depicted in FIG. 20, a voltage Vgs between the gate and the source of the reference transistor 110 or the measurement transistor 111 is a voltage obtained by subtracting the output voltage Vout0 from the input voltage Vin as expressed by the following Equation (9). In addition, a voltage Vds between the drain and the source of the reference transistor 110 or the measurement transistor 111 is a voltage obtained by subtracting the output voltage Vout0 from a power source voltage VDD as expressed by the following Equation (10). Considering herein that a saturation condition is that a voltage obtained by subtracting the threshold voltage Vth of the reference transistor 110 or the measurement transistor 111 and the voltage Vds between the drain and the source from the voltage Vgs between the gate and the source becomes lower than zero, a voltage obtained by subtracting the threshold voltage Vth and the power source voltage VDD from the input voltage Vin needs to become lower than zero as expressed by the following Equation (11).

$$\begin{matrix}[ Math . 1 ] & \\ Vgs = Vin - Vout 0 & ( 9 ) \\ Vds = VDD - Vout 0 & ( 10 ) \\ \begin{matrix}Vgs - Vth - Vds = ( Vin - Vout 0 ) - Vth - ( VDD - Vout 0 ) \\ = Vin - Vth - VDD < 0 \text{:} \\ saturation condition\end{matrix} & ( 11 )\end{matrix}$$

Further, a current Ids1 flowing between the drain and the source of the reference transistor 110 or the measurement transistor 111 can be obtained from the following Equation (12). Note that β1 in the Equation (12) is a gain of the reference transistor 110 or the measurement transistor 111.

$$\begin{matrix}[ Math . 2 ] & \\ Ids 1 = \frac{β 1 {( VDD - Vout 0 - Vth 1 )}^{2}}{2} & ( 12 )\end{matrix}$$

On the basis of the above, the output voltage Vout0 can be obtained from the following Equation (13).

$$\begin{matrix}[ Math . 3 ] & \\ Vout 0 = Vin - ( Vth + \sqrt{2 Ids 1 / β 1} ) \approx Vin - Vth & ( 13 )\end{matrix}$$

### (3.3.2. Specific Examples of Adjustment Circuit)

Next, the adjustment circuit according to the present embodiment will be described with several specific examples.

### (3.3.2.1. First Specific Example)

FIG. 21 is a circuit diagram depicting a general configuration example of an adjustment circuit according to a first specific example of the present embodiment. Note that, in the first specific example, a case where the adjustment circuit includes a limit circuit 361 which limits a change range of the output voltage Vout0 is described by giving an example thereof.

As depicted in FIG. 21, the limit circuit 361 according to the first specific example includes a load transistor 3611 which is short-circuited between a gate and a drain. The drain and the gate of the load transistor 3611 are connected to the sources of the reference transistor 110 and the measurement transistor 111, while a source of the load transistor 3611 is connected to the ground voltage VSS.

In such a configuration, a saturation condition of the load transistor 3611 is expressed by the following Equation (14). Further, the current Ids1 flowing between the drain and the source of the reference transistor 110 or the measurement transistor 111 is obtained from the following Equation (15), while a current Ids3 flowing between the drain and the source of the load transistor 3611 is obtained from the following Equation (16).

[Math. 4]

saturation condition: Vds>(Vgs−Vth) (14)

Ids1=β1(Vgs−Vth1)²

Vgs=VDD−Vout0

Ids1=β1(VDD−Vout0−Vth1)² (15)

Ids3=β3(Vout−Vth3)² (16)

A relation Ids1=Ids3 holds herein. Accordingly, a gain β3 of the load transistor 3611 can be obtained as expressed by the following Equation (17).

$$\begin{matrix}[ Math . 5 ] & \\ Ids 1 = Ids 3 \\ β 3 {( Vout 0 - Vth 3 )}^{2} = β 1 {( VDD - Vout 0 - Vth 1 )}^{2} \\ Vout = \frac{VDD - Vth 1 + \sqrt{\frac{β 3}{β 1}} Vth 3}{1 + \sqrt{\frac{β 3}{β 1}}} \\ β 1 = β 3 & ( 17 )\end{matrix}$$

As a result, the output voltage Vout0 can be reduced to substantially the half in comparison with the example depicted in FIG. 20, for example, as expressed by the following Equation (18). This indicates that the change range of the output voltage Vout0 is limited to substantially the half. Note that the output voltage Vout0 is input to the oscillation circuit 130.

[Math. 6]

Vout0=½(VDD−Vth1+Vth3) (18)

### (3.3.2.2. Second Specific Example)

FIG. 22 is a circuit diagram depicting a general configuration example of an adjustment circuit according to a second specific example of the present embodiment. Note that, in the second specific example, a case where the adjustment circuit includes a shift circuit 362 which shifts a change range of the output voltage Vout is described by giving an example.

As depicted in FIG. 22, the shift circuit 362 according to the second specific example is configured such that a first transistor 3621 of P type and a second transistor 3622 of N type connected in series, and a third transistor 3623 of P type and a fourth transistor 3624 of N type similarly connected in series are connected in parallel between the power source voltage VDD and the ground voltage VSS. In other words, the shift circuit 362 is configured such that two CMOS (Complementary Metal-Oxide-Semiconductor) circuits (hereinafter referred to as CMOS analog inverting circuits) each including a P-type transistor and an N-type transistor and connected in series are connected in series.

Drains of the first transistor 3621 and the second transistor 3622 are connected to each other. Similarly, drains of the third transistor 3623 and the fourth transistor 3624 are connected to each other.

The output voltage Vout from the source follower circuit is applied to a gate of the second transistor 3622. A gate of the first transistor 3621 is connected to the drain of the first transistor 3621 and the drain of the second transistor 3622 and is also connected to a gate of the third transistor 3623.

The drain of the third transistor 3623 and the drain of the fourth transistor 3624 are connected to a gate of the fourth transistor 3624 and are also connected to a circuit in a following stage (e.g., limit circuit 361 (or oscillation circuit 130)).

The shift circuit 362 having the configuration described above is capable of controlling a voltage value of a voltage output to a following stage, by controlling a ratio of an on-resistance of the P-type transistor (first transistor 3621 or third transistor 3623) to an on-resistance of the N-type transistor (second transistor 3622 or fourth transistor 3624) connected in series.

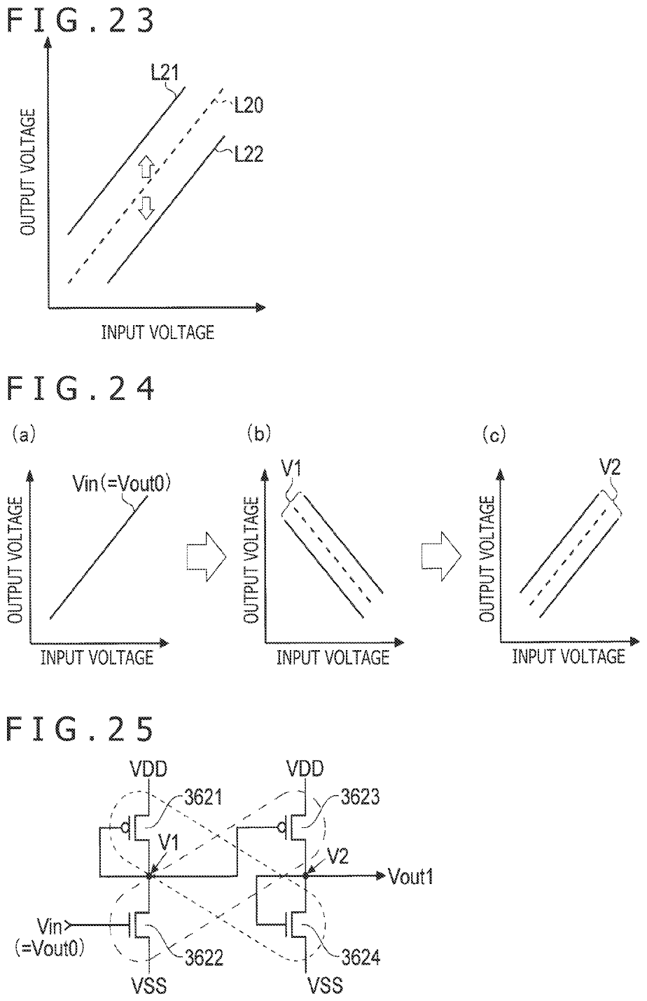

FIG. 23 is a diagram for explaining a shift of an output voltage in a case of control of the ratio of the on-resistance of the P-type transistor to the on-resistance of the N-type transistor in the shift circuit. In FIG. 23, a broken line L20 indicates a voltage value of a voltage V1 or V2 (corresponding to the output voltage Vout1 from the shift circuit 362) output to a following stage in a case where the on-resistance of the P-type transistor (first transistor 3621 or third transistor 3623) and the on-resistance of the N-type transistor (second transistor 3622 or fourth transistor 3624) have the same resistance value.

In FIG. 22, in a case where the on-resistance of the N-type transistor (second transistor 3622 or fourth transistor 3624) is higher than the on-resistance of the P-type transistor (first transistor 3621 or third transistor 3623), for example, the voltage V1 or V2 (output voltage Vout1) output to the following stage shifts toward the high voltage side as indicated by a solid line L21 in FIG. 23. On the other hand, in a case where the on-resistance of the P-type transistor (first transistor 3621 or third transistor 3623) is higher than the on-resistance of the N-type transistor (second transistor 3622 or fourth transistor 3624), for example, the voltage V1 or V2 (output voltage Vout1) output to the following stage shifts toward the low voltage side as indicated by a solid line L22 in FIG. 23.

However, in a case where one or an odd number of the CMOS analog inverting circuits each including the P-type transistor and the N-type transistor connected in series are provided, the voltage output to the following stage (e.g., the voltage V1 in the examples presented in FIGS. 22 and 24) has an inverted voltage value with respect to the input voltage Vin as indicated in (a) and (b) of FIG. 24. According to the present embodiment, two or an even number of the CMOS analog inverting circuits each including the P-type transistor and the N-type transistor are therefore provided to reinvert the output voltage as indicated in (c) of FIG. 24 (e.g., the voltage V2 in the examples presented in FIGS. 22 and 24).

Note that the voltage value of the output voltage Vout1 needs to be raised in a case where the oscillation frequency f of the oscillation circuit 130 is desired to be increased, and the voltage value of the output voltage Vout1 needs to be lowered in a case where the oscillation frequency f is desired to be decreased as depicted in FIG. 25. In a case where the voltage value of the output voltage Vout1 is to be raised, the on-resistance of each of the second transistor 3622 and the third transistor 3623 located at opposite diagonal positions is decreased. In such a case, the on-resistance of the first transistor 3621 and the fourth transistor 3624 located at opposite diagonal positions may be increased. On the other hand, in a case where the voltage value of the output voltage Vout1 is to be lowered, the on-resistance of each of the second transistor 3622 and the third transistor 3623 is increased. In such a case, the on-resistance of the first transistor 3621 and the fourth transistor 3624 may be decreased.

The increase and decrease of the on-resistance of each of the transistors may be achieved by using methods such as adjustment of a gate length (length L) or a gate width (width W) of each of the transistors or adjustment of the number of Fingers of each of the transistors.

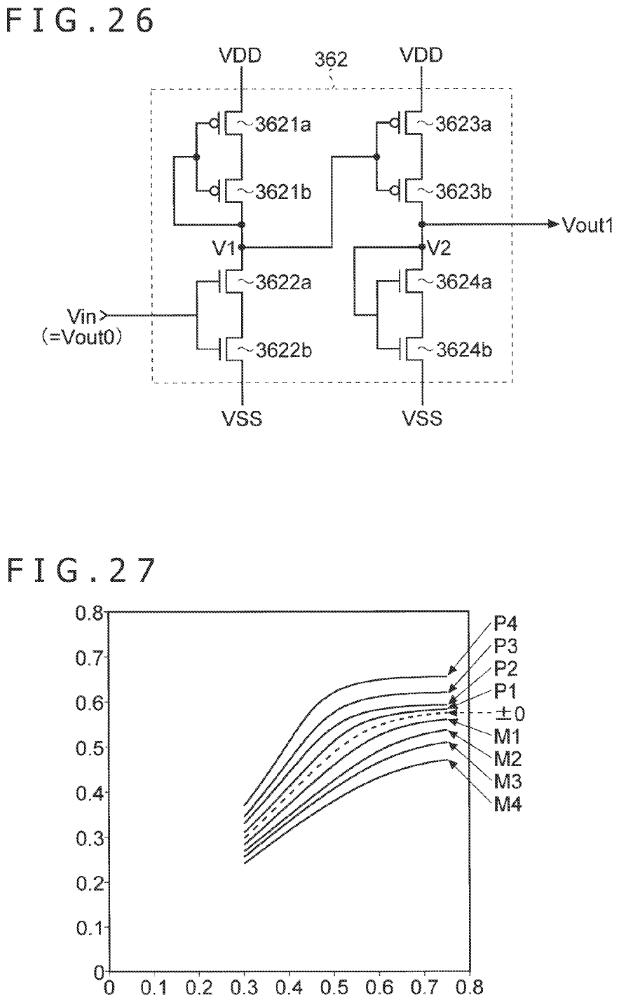

FIG. 26 is a circuit diagram depicting a general configuration example of the shift circuit 362 in a case where the number of Fingers of each of the first to fourth transistors 3621 to 3624 is 2. For example, the first transistor 3621 includes two transistors 3621a and 3621b, the second transistor 3622 includes two transistors 3622a and 3622b, the third transistor 3623 includes two transistors 3623a and 3623b, and the fourth transistor 3624 includes two transistors 3624a and 3624b.

FIG. 27 is a graph representing an example of an output voltage output from the shift circuit in a case where the number of Fingers of each of the first to fourth transistors is switched. In FIG. 27, a broken line ±0 indicates a case where the number of Fingers of each of the first to fourth transistors 3621 to 3624 is 1. In addition, a curved line P1 indicates a case where the total number of Fingers of the second transistor 3622 and the third transistor 3623 is 3 and where the total number of Fingers of the first transistor 3621 and the fourth transistor 3624 is 2. A curved line P2 indicates a case where the total number of Fingers of the second transistor 3622 and the third transistor 3623 is 3 and where the total number of Fingers of the first transistor 3621 and the fourth transistor 3624 is 1. A curved line P3 indicates a case where the total number of Fingers of the second transistor 3622 and the third transistor 3623 is 4 and where the total number of Fingers of the first transistor 3621 and the fourth transistor 3624 is 2. A curved line P4 indicates a case where the total number of Fingers of the second transistor 3622 and the third transistor 3623 is 4 and where the total number of Fingers of the first transistor 3621 and the fourth transistor 3624 is 1. Further, a curved line M1 indicates a case where the total number of Fingers of the second transistor 3622 and the third transistor 3623 is 2 and where the total number of Fingers of the first transistor 3621 and the fourth transistor 3624 is 3. A curved line M2 indicates a case where the total number of Fingers of the second transistor 3622 and the third transistor 3623 is 1 and where the total number of Fingers of the first transistor 3621 and the fourth transistor 3624 is 3. A curved line M3 indicates a case where the total number of Fingers of the second transistor 3622 and the third transistor 3623 is 2 and where the total number of Fingers of the first transistor 3621 and the fourth transistor 3624 is 4. A curved line M4 indicates a case where the total number of Fingers of the second transistor 3622 and the third transistor 3623 is 1 and where the total number of Fingers of the first transistor 3621 and the fourth transistor 3624 is 4.

As described above, in the configuration where the eight transistors in total are cascode-connected, the voltage value of the output voltage Vout1 is adjustable to nine levels by adjusting the number of Fingers of each of the transistors.

### (3.3.2.3. Third Specific Example)

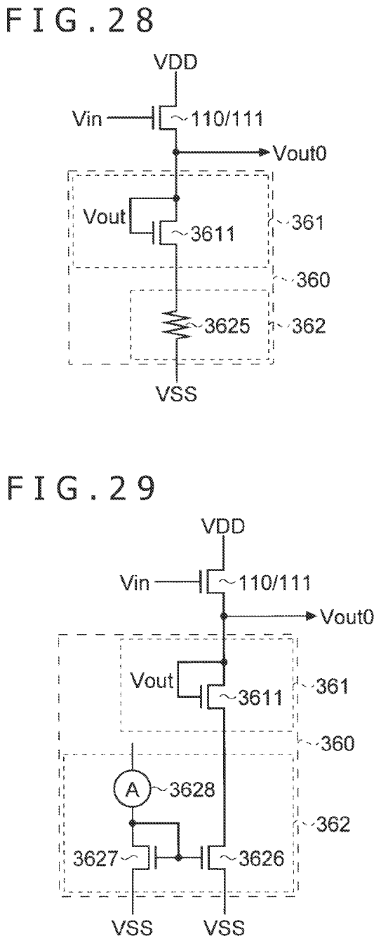

FIG. 28 is a circuit diagram depicting a general configuration example of an adjustment circuit according to a third specific example of the present embodiment. As depicted in FIG. 28, an adjustment circuit 360 according to the third specific example may be configured such that the limit circuit 361 and the shift circuit 362 are connected in series with respect to the source follower circuit including the measurement transistor 111 and the reference transistor 110. Further, the shift circuit 362 may include a resistance element 3625.

The output voltage Vout0 can be shifted toward the high voltage side by providing the resistance element 3625 on the source side of the source follower circuit. Note that, in a case of shifting the output voltage Vout0 toward the low voltage side, it is sufficient if the resistance element 3625 is provided on the drain side of the source follower circuit.

### (3.3.2.4. Fourth Specific Example)

FIG. 29 is a circuit diagram depicting a general configuration example of an adjustment circuit according to a fourth specific example of the present embodiment. As depicted in FIG. 29, an adjustment circuit 360 according to the fourth specific example is configured similarly to the adjustment circuit 360 according to the third specific example, but is configured such that the shift circuit 362 is replaced with a circuit configuration including two transistors 3626 and 3627 and a constant current circuit 3628.

Gates of the two transistors 3626 and 3627 are connected to a drain of the transistor 3627, which is one of the two transistors 3626 and 3627, to form a current mirror circuit. The drain of the transistor 3627 is connected to the constant current circuit 3628.

According to such a configuration, the transistor 3626, which is one of the transistors included in the current mirror circuit, has a function of limiting a current flowing in the source follower circuit. Accordingly, the output voltage Vout0 can be shifted toward the high voltage side by controlling a current flowing in the constant current circuit 3628. Note that, in a case of shifting the output voltage Vout0 toward the low voltage side, it is sufficient if the shift circuit 362 is provided on the drain side of the source follower circuit.

### (3.3.2.5. Other Examples)

Further, for example, the output voltage Vout0 can also be shifted by adjusting a ratio of the on-resistance of the measurement transistor 111 or the reference transistor 110 to the on-resistance of the load transistor 3611 in the configuration described with reference to FIG. 21. Note that the increase and decrease of the on-resistance of each of the transistors may be achieved by using methods such as adjustment of a gate length (length L) or a gate width (width W) of each of the transistors or adjustment of the number of Fingers of each of the transistors.

### (3.4. Structure Example)

Next, a structure of a semiconductor device according to the present embodiment will be described by giving several examples with reference to the drawings. Note that the limit circuit 361 and the shift circuit 362 in the following description may be similar to the limit circuit 361 and the shift circuit 362 presented by way of example in the above description of the adjustment circuit 360.

### (3.4.1. First Example)

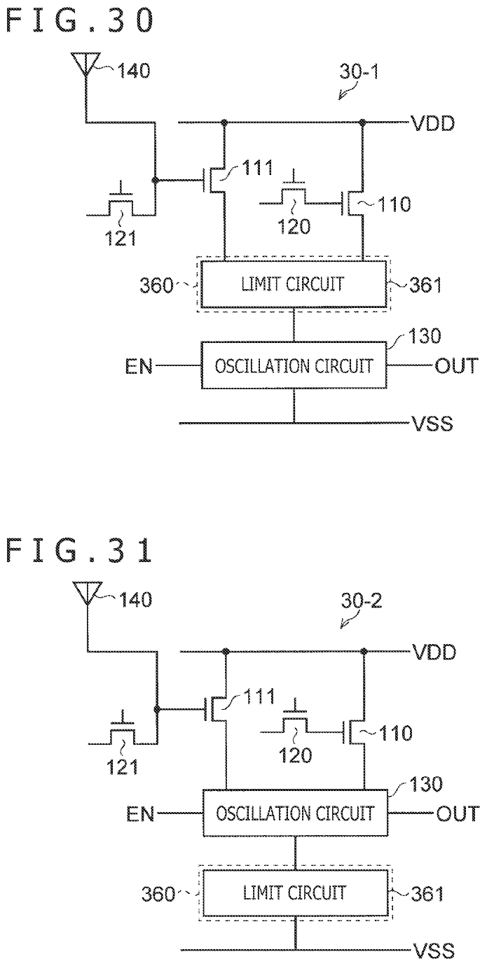

FIG. 30 is a circuit diagram explaining a structure example of a semiconductor device according to a first example of the present embodiment. As depicted in FIG. 30, for example, a semiconductor device 30-1 according to the first example is configured similarly to the semiconductor device 10 described in the first embodiment with reference to FIG. 3, but has such a structure that the adjustment circuit 360 including the limit circuit 361 is provided on the source side of the source follower circuit including the measurement transistor 111 and the reference transistor 110.

### (3.4.2. Second Example)

FIG. 31 is a circuit diagram explaining a structure example of a semiconductor device according to a second example of the present embodiment. As depicted in FIG. 31, for example, a semiconductor device 30-2 according to the second example is configured similarly to the semiconductor device 30-1 depicted in FIG. 30, but has such a structure that the adjustment circuit 360 including the limit circuit 361 is provided between the oscillation circuit 130 and the ground voltage VSS.

### (3.4.3. Third Example)

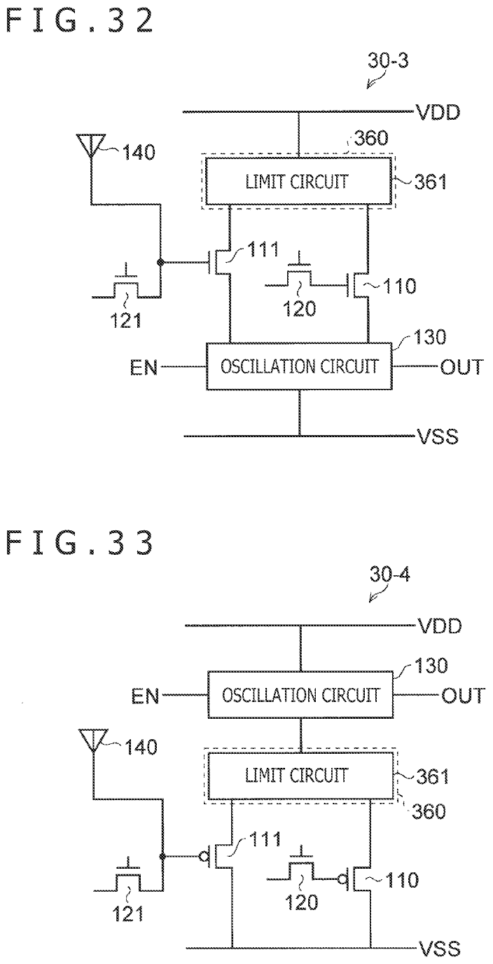

FIG. 32 is a circuit diagram explaining a structure example of a semiconductor device according to a third example of the present embodiment. As depicted in FIG. 32, for example, a semiconductor device 30-3 according to the third example is configured similarly to the semiconductor device 30-1 depicted in FIG. 30, but has such a structure that the adjustment circuit 360 including the limit circuit 361 is provided on the drain side of the source follower circuit.

### (3.4.4. Fourth Example)

FIG. 33 is a circuit diagram explaining a structure example of a semiconductor device according to a fourth example of the present embodiment. As depicted in FIG. 33, for example, a semiconductor device 30-4 according to the fourth example is configured similarly to the semiconductor device 30-3 depicted in FIG. 32, but has such a structure that the oscillation circuit 130 is provided between the adjustment circuit 360 and the power source voltage VDD.

### (3.4.5. Fifth Example)

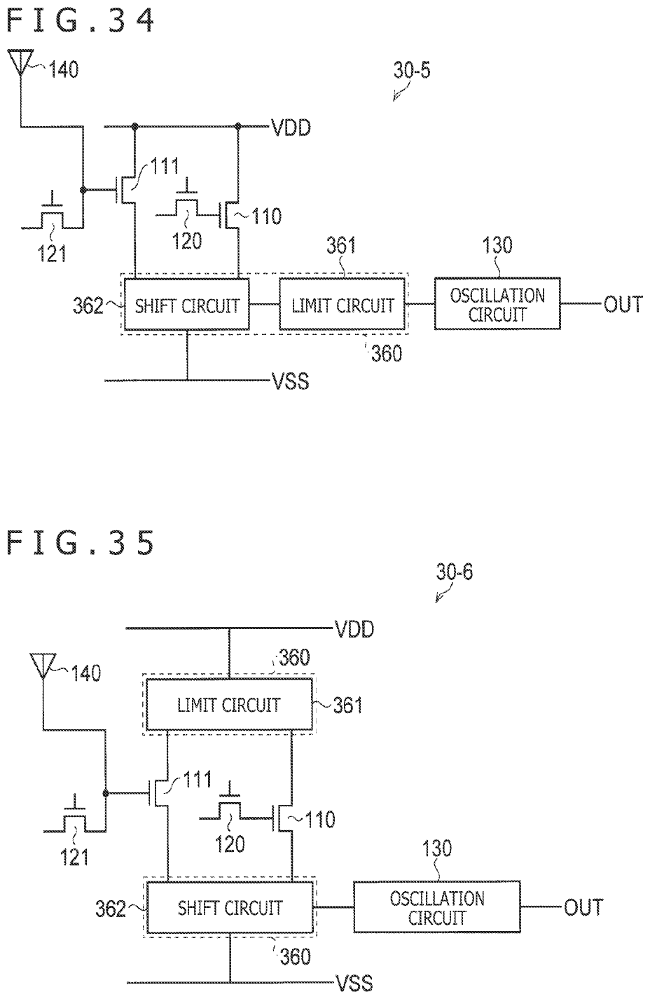

FIG. 34 is a circuit diagram explaining a structure example of a semiconductor device according to a fifth example of the present embodiment. As depicted in FIG. 34, for example, a semiconductor device 30-5 according to the fifth example is configured similarly to the semiconductor device 10 described in the first embodiment with reference to FIG. 3, but has such a structure that shift circuit 362 is connected to the source side of the source follower circuit including the measurement transistor 111 and the reference transistor 110 and that the limit circuit 361 is connected to the output of the shift circuit 362.

### (3.4.6. Sixth Example)

FIG. 35 is a circuit diagram explaining a structure example of a semiconductor device according to a sixth example of the present embodiment. As depicted in FIG. 35, for example, a semiconductor device 30-6 according to the sixth example is configured similarly to the semiconductor device 30-5 depicted in FIG. 34, but has such a structure that the limit circuit 361 is connected to the drain side of the source follower circuit and that the oscillation circuit 130 is connected to the output of the shift circuit 362.

### (3.4.7. Other Examples)

Note that, a case where the measurement transistor 111 and the reference transistor 110 included in the source follower circuit are each an N-type transistor is described by way of example in each of the first to sixth examples described above, but the configuration is not limited thereto. Specifically, in the present embodiment, the measurement transistor 111 and the reference transistor 110 can each be configured as a P-type transistor. In such a case, for example, the power source voltage VDD and the ground voltage VSS are switched to each other in the structure described in each of the first to sixth examples.

### (3.5. Demonstration Experiment Result)

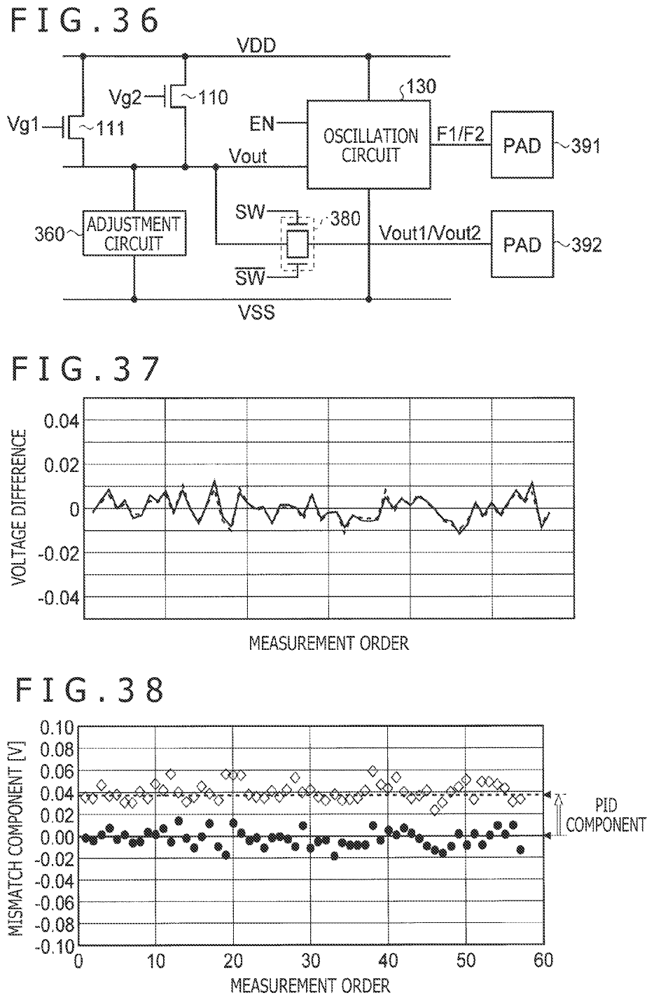

An effect produced by providing the adjustment circuit 360 described above will subsequently be described on the basis of a demonstration experiment result. FIG. 36 is a diagram depicting a circuit configuration of a semiconductor device used to execute the present demonstration experiment. In addition, FIG. 37 is a graph representing a result obtained by the present demonstration experiment.

As depicted in FIG. 36, used in the present demonstration experiment is a semiconductor device which includes the adjustment circuit 360 provided on the source side of the source follower circuit including the measurement transistor 111 and the reference transistor 110. The limit circuit 361 according to the first specific example described with reference to FIG. 21 is adopted as the adjustment circuit 360.

According to such a semiconductor device, the output voltage Vout output from the source follower circuit is input to the oscillation circuit 130. An oscillation frequency of the oscillation circuit 130 is measured through an output pad 391. A ring oscillator is adopted as the oscillation circuit 130.

Further, according to the present demonstration experiment, the output of the source follower circuit is branched and connected to an output pad 392 through a switch 380 to directly measure the output voltage Vout from the source follower circuit.

In the present demonstration experiment, directly measured through the output pad 392 in the above configuration are the output voltage Vout (designated as output voltage Vout1) output from the source follower circuit when a voltage Vg1 is applied to the measurement transistor 111, and the output voltage Vout (designated as output voltage Vout2) output from the source follower circuit when a voltage Vg2 is applied to the reference transistor 110, by turning on the switch 380 in an off-state of an enable signal EN input to the oscillation circuit 130. Further, in the present demonstration experiment, also measured through the output pad 391 are an oscillation frequency F1 of the oscillation circuit 130 when the voltage Vg1 is applied to the measurement transistor 111, and an oscillation frequency F2 of the oscillation circuit 130 when the voltage Vg2 is applied to the reference transistor 110, by turning on the state enable signal EN in an off-state of the switch 380.

In FIG. 37, a broken line represents plotted values obtained by subtracting the oscillation frequency F1 from the oscillation frequency F2 and then multiplying a difference thus obtained by a predetermined proportional multiplier, while a solid line represents plotted values obtained by subtracting the output voltage Vout1 from the output voltage Vout2. As apparent with reference to FIG. 37, the values obtained by subtracting the oscillation frequency F1 from the oscillation frequency F2 and then multiplying the difference by the predetermined proportional multiplier are substantially equivalent to the values of the difference obtained by subtracting the output voltage Vout1 from the output voltage Vout2. This indicates that a change of the output voltage Vout can be acquired by multiplying a frequency difference by a proportional multiplier.

### (3.5.1. Effect of Threshold Voltage of Load Transistor Included in Limit Circuit)

Described herein will be an effect of the threshold voltage Vth of the load transistor 3611 included in the limit circuit 361, on the output voltage Vout from the source follower circuit.

The output voltage Vout2 output when the voltage Vg2 is applied to the reference transistor 110 can be calculated by the following Equation (19), while the output voltage Vout1 output when the voltage Vg1 is applied to the measurement transistor 111 can be calculated by the following Equation (20).

[Math. 7]

Vout2=½(VDD−Vth2+Vth3) (19)

Vout1=½(VDD−Vth1+Vth3) (20)

Assuming herein that a design value of the threshold voltage of each transistor is Vth, that a variation of the threshold voltage Vth1 of the measurement transistor 111 is δVth1, that a variation of the threshold voltage Vth2 of the reference transistor 110 is δVth2, and that a shift amount of the threshold voltage Vth1 produced by damage given from an antenna is ΔPID, the threshold voltage Vth2 of the reference transistor 110 is expressed by the following Equation (21), and the threshold voltage Vth1 of the measurement transistor 111 is expressed by the following Equation (22).

[Math. 8]

Vth1=Vth+δVth1+ΔPID (21)

Vth2=Vth+δVth2 (21)

Accordingly, as apparent from the following Equation (23), a difference (−δVth2+δVth1) between the variation δVth2 of the threshold voltage Vth2 of the reference transistor 110 and the variation δVth1 of the threshold voltage Vth1 of the measurement transistor 111 (hereinafter also referred to as a mismatch component) and a component of the shift amount ΔPID of the threshold voltage Vth1 produced by damage from the antenna remain in a case of subtracting the output voltage Vout1 from the output voltage Vout2.

[Math. 9]

Vout2−Vout1=½(−δVth2+δVth1+ΔPID) (23)

The output voltage Vout is input to the oscillation circuit 130 and converted into the oscillation frequency f. The oscillation frequency f at the output voltage Vout2 is F2, while the oscillation frequency f at the output voltage Vout1 is F1. In addition, the oscillation frequency f is allowed to change into a voltage value by using a function G(f) as expressed by the following Equation (24) and Equation (25).

[Math. 10]

G(F2)=Vout2 (24)

G(F1)=Vout1 (25)

According to the present embodiment, linear approximation can be used as described above. Therefore, each of the threshold voltages Vth1 and Vth2 can be approximated in a manner expressed by the following Equation (26) in a case where k is a coefficient (proportional multiplier).

[Math. 11]

Vout1=k*F1,Vout2=k*F2 (26)

Accordingly, the difference between the threshold voltage Vth2 of the reference transistor 110 and the threshold voltage Vth1 of the measurement transistor 111, that is, the shift amount ΔPID of the threshold voltage Vth1 produced by damage from the antenna, can be calculated in a manner expressed by the following Equation (27).

[Math. 12]

Vout2−Vout1=k*(F2−F1)=½(−δVth2+δVth1+ΔPID)

ΔPID=2k*(F2−F1)−(δVth1−δVth2) (27)

Note that the mismatch component (δVth1−δVth2) remains in the Equation (27). This mismatch component is a completely random value and can therefore be reduced to an ignorable level by measuring a sufficient number of samples and averaging the samples.

FIG. 38 is a graph representing an example of voltage values of mismatch components in a case of the presence of damage from the antenna and in a case of the absence of damage from the antenna. In FIG. 38, each of circles filled in black indicates the threshold voltage in the case of the absence of damage from the antenna, while each of white circles indicates the threshold voltage in the case of the presence of damage from the antenna.

As presented in FIG. 38, an average of the threshold voltages Vth is −0.0004 [V] in the case of the absence of damage from the antenna, while an average of the threshold voltages Vth is 0.039 [V] in the case of the presence of damage from the antenna. This indicates that the threshold voltage Vth of the measurement transistor 111 has shifted by 0.039 V on average due to the damage from the antenna.

### (3.6. Summary)

As described above, according to the present embodiment, achieved are a semiconductor device, a detection method, an electronic apparatus, and an electronic apparatus control method capable of calculating a change amount of the channel resistance R1 or the threshold voltage Vth resulting from PID by a simple and easy method using linear approximation.

Other configurations, operations, and effects may be similar to those of the embodiments described above and are therefore not repeatedly described in detail herein.

The technical scope of the present disclosure is not limited to the preferred embodiments of the present disclosure described above in detail with reference to the accompanying drawings. It is obvious that those having ordinary knowledges in the technical field of the present disclosure can conceive of various modifications or corrections within the scope of the technical ideas described in the claims. It is therefore understood that these modifications and corrections belong to the technical scope of the present disclosure as a matter of course.

Further, the advantageous effects described in the present description are presented only by way of explanation or example and are not restrictive. In other words, the technology according to the present disclosure may offer other advantageous effects apparent for those skilled in the art in the light of the present description, in addition to or in place of the advantageous effects described above.

Note that following configurations also belong to the technical scope of the present disclosure.

(1)

A semiconductor device including:

at least one measurement transistor a gate of which is electrically connected to an antenna unit that functions as an antenna in a plasma process;

a selection transistor a source of which is electrically connected to the gate of the measurement transistor in parallel to the antenna unit; and

an oscillation circuit electrically connected to a source of the measurement transistor and having an oscillation frequency that changes according to a threshold voltage of the measurement transistor.

(2)

The semiconductor device according to (1) described above, in which

the oscillation circuit is provided between a VDD wire and a VSS wire, and

the measurement transistor is provided between the oscillation circuit and the VDD wire or the VSS wire.

(3)

The semiconductor device according to (2) described above, in which

the oscillation circuit includes a ring oscillator.

(4)

The semiconductor device according to (1) described above, in which

the oscillation circuit includes an oscillation circuit that outputs an oscillation frequency that changes according to an input voltage, and

an input of the oscillation circuit is electrically connected to the source of the measurement transistor in parallel to a load element.

(5)

The semiconductor device according to (4) described above, in which

the load element includes a resistance element.

(6)

The semiconductor device according to any one of (1) to (5) described above, in which

the measurement transistor and the selection transistor are of the same conductivity type.

(7)

The semiconductor device according to any one of (1) to (6) described above, in which

a plurality of the measurement transistors is provided,

the measurement transistor provided on a VDD wire side with respect to the oscillation circuit includes an N-type transistor, and

the measurement transistor provided on a VSS wire side with respect to the oscillation circuit includes a P-type transistor.

(8)

The semiconductor device according to any one of (1) to (7) described above, in which

a plurality of the measurement transistors is provided, and an area ratio of the antenna unit to the gate differs for each of the plurality of measurement transistors.

(9)

The semiconductor device according to any one of (1) to (8) described above, in which

a protection element is further electrically connected to the gate of the measurement transistor.

(10)

The semiconductor device according to any one of (1) to (9) described above, in which

the selection transistor is electrically connected to the measurement transistor through a wire located in a layer above the antenna unit, and

a protection element is electrically connected to the wire.

The semiconductor device according to any one of (1) to (10) described above, in which

a body of the measurement transistor is electrically connected to the source of the measurement transistor.

(12)

The semiconductor device according to any one of (1) to (11) described above, further including:

a reference transistor a source of which is electrically connected to the oscillation circuit without electric connection between the antenna unit and a gate of the reference transistor; and

a reference selection transistor a source of which is electrically connected to the gate of the reference transistor.

(13)

The semiconductor device according to any one of (1) to (12) described above, further including:

an adjustment circuit that adjusts a voltage value of a voltage appearing in the source of the measurement transistor.

(14)

The semiconductor device according to (13) described above, in which

the adjustment circuit is connected to at least either the source or a drain of the measurement transistor.

(15)

The semiconductor device according to (13) or (14) described above, in which

the adjustment circuit includes a resistance element.

(16)

The semiconductor device according to (13) or (14) described above, in which

the adjustment circuit includes a CMOS (Complementary Metal-Oxide-Semiconductor) element.

(17)

The semiconductor device according to any one of (13) to (16) described above, in which

the oscillation circuit includes an oscillation circuit that outputs an oscillation frequency that changes according to a voltage value of an input voltage, and

an input of the oscillation circuit is electrically connected to the source of the measurement transistor in parallel to a load element.

(18)

A detection method including:

controlling a measurement transistor of a semiconductor device to be brought into an on-state by controlling a selection transistor of the semiconductor device to be brought into an on-state, the semiconductor device including
at least the one measurement transistor a gate of which is electrically connected to an antenna unit that functions as an antenna in a plasma process,
the selection transistor a source of which is electrically connected to the gate of the measurement transistor in parallel to the antenna unit, and
an oscillation circuit electrically connected to a source of the measurement transistor and having an oscillation frequency that changes according to a threshold voltage of the measurement transistor; and

measuring an oscillation frequency of the oscillation circuit when the measurement transistor is in the on-state, and detecting presence or absence of a difference between the threshold voltage of the measurement transistor and an ideal value of the threshold voltage on the basis of the measured oscillation frequency.

(19)

An electronic apparatus including:

a semiconductor device that includes
at least one measurement transistor a gate of which is electrically connected to an antenna unit that functions as an antenna in a plasma process,
a selection transistor a source of which is electrically connected to the gate of the measurement transistor in parallel to the antenna unit, and
an oscillation circuit electrically connected to a source of the measurement transistor and having an oscillation frequency that changes according to a threshold voltage of the measurement transistor;

a control unit that controls an on-state or an off-state of the measurement transistor by controlling an on-state or an off-state of the selection transistor;

a measurement unit that measures an oscillation frequency of the oscillation circuit when the measurement transistor is in the on-state;

a detection unit that detects presence or absence of a difference between the threshold voltage of the measurement transistor and an ideal value of the threshold voltage on the basis of each of the measured oscillation frequencies; and

a processing unit that performs processing of correcting an effect produced by the plasma process in a case where the difference is detected by the detection unit.

(20)

An electronic apparatus control method including:

controlling a measurement transistor of an electronic apparatus to be brought into an on-state by controlling a selection transistor of the electronic apparatus to be brought into an on-state, the electronic apparatus including a semiconductor device that includes
at least the one measurement transistor a gate of which is electrically connected to an antenna unit that functions as an antenna in a plasma process,
the selection transistor a source of which is electrically connected to the gate of the measurement transistor in parallel to the antenna unit, and
an oscillation circuit electrically connected to a source of the measurement transistor and having an oscillation frequency that changes according to a threshold voltage of the measurement transistor;

measuring an oscillation frequency of the oscillation circuit when the measurement transistor is in the on-state, and detecting presence or absence of a difference between the threshold voltage of the measurement transistor and an ideal value of the threshold voltage on the basis of the measured oscillation frequency; and

performing control to correct an effect produced by the plasma process in a case where the difference is detected.

### REFERENCE SIGNS LIST

10, 10A, 11, 12, 13, 14, 20, 30-1 to 30-6: Semiconductor device
101: Control unit
102: Measurement unit
103: Detection unit
104: Processing unit
110, 210: Reference transistor
111, 111A, 112, 211, 212: Measurement transistor
120, 220: Reference selection transistor
121, 122, 221, 222: Selection transistor
130, 230: Oscillation circuit
131: P-type transistor
132: N-type transistor
133: Load capacitance
140, 141, 142, 241, 242: Antenna unit
150: Protection element
250: Load element
360: Adjustment circuit
361: Limit circuit
362: Shift circuit
380: Switch
391, 392: Output pad
1000, 1001, 1002: Electronic apparatus
1101, 1102: Body circuit
1201: Reference voltage control circuit
1202: PID resistance block switching control circuit
1301: Reference voltage generation circuit
1302: PID low resistance circuit
1402: PID high resistance circuit
3611: Load transistor
3621: First transistor
3621a, 3621b, 3622a, 3622b, 3623a, 3623b, 3624a, 3624b, 3626, 3627: Transistor
3622: Second transistor
3623: Third transistor
3624: Fourth transistor
3625: Resistance element
3628: Constant current circuit

What is claimed is:

1. A semiconductor device comprising:
at least one measurement transistor a gate of which is electrically connected to an antenna unit that functions as an antenna in a plasma process;
a selection transistor a source of which is electrically connected to the gate of the measurement transistor in parallel to the antenna unit; and
an oscillation circuit electrically connected to a source of the measurement transistor and having an oscillation frequency that changes according to a threshold voltage of the measurement transistor.

2. The semiconductor device according to claim 1, wherein
the oscillation circuit is provided between a VDD wire and a VSS wire, and
the measurement transistor is provided between the oscillation circuit and the VDD wire or the VSS wire.

3. The semiconductor device according to claim 2, wherein
the oscillation circuit includes a ring oscillator.

4. The semiconductor device according to claim 1, wherein
the oscillation circuit includes an oscillation circuit that outputs an oscillation frequency that changes according to an input voltage, and
an input of the oscillation circuit is electrically connected to the source of the measurement transistor in parallel to a load element.

5. The semiconductor device according to claim 4, wherein
the load element includes a resistance element.

6. The semiconductor device according to claim 1, wherein
the measurement transistor and the selection transistor are of a same conductivity type.

7. The semiconductor device according to claim 1, wherein
a plurality of the measurement transistors is provided,
the measurement transistor provided on a VDD wire side with respect to the oscillation circuit includes an N-type transistor, and
the measurement transistor provided on a VSS wire side with respect to the oscillation circuit includes a P-type transistor.

8. The semiconductor device according to claim 1, wherein
a plurality of the measurement transistors is provided, and
an area ratio of the antenna unit to the gate differs for each of the plurality of measurement transistors.

9. The semiconductor device according to claim 1, wherein
a protection element is further electrically connected to the gate of the measurement transistor.

10. The semiconductor device according to claim 1, wherein
the selection transistor is electrically connected to the measurement transistor through a wire located in a layer above the antenna unit, and
a protection element is electrically connected to the wire.

11. The semiconductor device according to claim 1, wherein
a body of the measurement transistor is electrically connected to the source of the measurement transistor.

12. The semiconductor device according to claim 1, further comprising:
a reference transistor a source of which is electrically connected to the oscillation circuit without electric connection between the antenna unit and a gate of the reference transistor; and
a reference selection transistor a source of which is electrically connected to the gate of the reference transistor.

13. The semiconductor device according to claim 1, further comprising:
an adjustment circuit that adjusts a voltage value of a voltage appearing in the source of the measurement transistor.

14. The semiconductor device according to claim 13, wherein
the adjustment circuit is connected to at least either the source or a drain of the measurement transistor.

15. The semiconductor device according to claim 13, wherein
the adjustment circuit includes a resistance element.

16. The semiconductor device according to claim 13, wherein
the adjustment circuit includes a CMOS (Complementary Metal-Oxide-Semiconductor) element.

17. The semiconductor device according to claim 13, wherein
the oscillation circuit includes an oscillation circuit that outputs an oscillation frequency that changes according to a voltage value of an input voltage, and
an input of the oscillation circuit is electrically connected to the source of the measurement transistor in parallel to a load element.

18. A detection method comprising:
controlling a measurement transistor of a semiconductor device to be brought into an on-state by controlling a selection transistor of the semiconductor device to be brought into an on-state, the semiconductor device including
at least the one measurement transistor a gate of which is electrically connected to an antenna unit that functions as an antenna in a plasma process,
the selection transistor a source of which is electrically connected to the gate of the measurement transistor in parallel to the antenna unit, and
an oscillation circuit electrically connected to a source of the measurement transistor and having an oscillation frequency that changes according to a threshold voltage of the measurement transistor; and
measuring an oscillation frequency of the oscillation circuit when the measurement transistor is in the on-state, and detecting presence or absence of a difference between the threshold voltage of the measurement transistor and an ideal value of the threshold voltage on a basis of the measured oscillation frequency.

19. An electronic apparatus comprising:
a semiconductor device that includes
at least one measurement transistor a gate of which is electrically connected to an antenna unit that functions as an antenna in a plasma process,
a selection transistor a source of which is electrically connected to the gate of the measurement transistor in parallel to the antenna unit, and
an oscillation circuit electrically connected to a source of the measurement transistor and having an oscillation frequency that changes according to a threshold voltage of the measurement transistor;
a control unit that controls an on-state or an off-state of the measurement transistor by controlling an on-state or an off-state of the selection transistor;
a measurement unit that measures an oscillation frequency of the oscillation circuit when the measurement transistor is in the on-state;
a detection unit that detects presence or absence of a difference between the threshold voltage of the measurement transistor and an ideal value of the threshold voltage on a basis of each of the measured oscillation frequencies; and
a processing unit that performs processing of correcting an effect produced by the plasma process in a case where the difference is detected by the detection unit.

20. An electronic apparatus control method comprising:
controlling a measurement transistor of an electronic apparatus to be brought into an on-state by controlling a selection transistor of the electronic apparatus to be brought into an on-state, the electronic apparatus including a semiconductor device that includes
at least the one measurement transistor a gate of which is electrically connected to an antenna unit that functions as an antenna in a plasma process,
the selection transistor a source of which is electrically connected to the gate of the measurement transistor in parallel to the antenna unit, and
an oscillation circuit electrically connected to a source of the measurement transistor and having an oscillation frequency that changes according to a threshold voltage of the measurement transistor;
measuring an oscillation frequency of the oscillation circuit when the measurement transistor is in the on-state, and detecting presence or absence of a difference between the threshold voltage of the measurement transistor and an ideal value of the threshold voltage on a basis of the measured oscillation frequency; and
performing control to correct an effect produced by the plasma process in a case where the difference is detected.
